(19) United States
(12) Patent Application Publication
(10) Pub. No.: US 2024/0321949 A1
(43) Pub. Date: Sep. 26, 2024

(54) JUNCTION TERMINATION STRUCTURE

(71) Applicant: RISE Research Institutes of Sweden AB, Borås (SE)

(72) Inventors: Mietek BAKOWSKI, Stillingsön (SE); Ulf GISSLANDER, Linköping (SE)

(73) Assignee: RISE Research Institutes of Sweden AB, Borås (SE)

(21) Appl. No.: 18/578,028

(22) PCT Filed: Jun. 28, 2022
(86) PCT No.: PCT/EP2022/067720

§ 371 Date: Jan. 10, 2024

(30) Foreign Application Priority Data
Jul. 16, 2021 (EP) 21186098.6

(51) Int. Cl. H01L 29/06; H01L 21/265

(52) U.S. Cl. CPC H01L 29/0619; H01L 21/265

(57) ABSTRACT

A semiconductor device (1) is provided and a method of manufacturing the same. The method comprising providing a substrate (2) having formed thereon or therein a main junction (3). The method further comprises forming a junction termination structure (5) comprising a plurality of junction termination paths (8b-8g), wherein each path comprises an implanted region (9b-9g) having an implanted width. The step of forming a junction termination structure further comprises determining an individual width for each implanted width and a single first dopant dose which corresponds to an individual effective sheet charge concentration for each path such that, when said semiconductor device is in use, a desired electric field distribution over the second region of the semiconductor device is achieved. The step of forming a junction termination structure further comprises doping the implanted regions, each having the individual width, with dopants according to said first single dopant dose.

### TECHNICAL FIELD

The present invention relates to voltage blocking p-n junction in semiconductor devices. More specifically, the invention relates to a semiconductor device comprising a junction termination and a method of forming the same.

### BACKGROUND

Semiconductor devices require a junction termination in order to maintain as high voltage blocking capability as possible of the semiconductor device. Typically, the semiconductor device comprises a main voltage blocking junction, formed between metal and semiconductor or between two semiconductor regions intentionally doped to be p- and n-type creating a Schottky or a p-n junction, respectively, being designed for a certain design voltage. With increasing voltage applied over the main junction, the electric field in the periphery of the main junction will increase, i.e. electric field crowding will occur at the periphery of the main junction in the absence of the junction termination. Normally, at some voltage level lower than the design voltage for which the main junction is designed (breakdown voltage), the electric field reaches critical electric field value characteristic for the semiconductor material giving rise to the so called impact ionization of charge carriers which occurs when electrons obtain high enough kinetic energy between collisions with atoms of the host material to release (kick-out) new free electrons, also known as avalanche breakdown. This will result in a premature breakdown occurring in the periphery area of the main junction and significant lowering of the voltage blocking capability of the semiconductor device. In order to solve the above problem junction termination structures may be applied next to and surrounding the main junction in order to spread the electric field out over a greater area, thereby reducing the electric field crowding. A solution for this is presented in US2014048903A1 where an edge termination structure is applied comprising so called free floating field limiting rings. The rings have a relatively high doping preventing the electric potential to reach the device surface under the rings but at the same time forcing the electric potential to be distributed in the areas (spaces) in-between the rings, resulting in periodic peaks in the electric field along the peripheral area of the main junction, and in that way providing an decreased electric field however at the expense of the semiconductor area. Another approach is presented in US2015021742 A1 where a junction termination extension is formed on the substrate adjacent the power semiconductor device, the junction termination extension including a plurality of junction termination zones that are doped with dopants. After measuring a leakage current of the power semiconductor device, the junction termination extension is etched in order to reduce the effective doping concentration within the junction termination extension to the desired level.

### SUMMARY OF THE INVENTION

It is an object of the present inventive concept to mitigate, alleviate or eliminate one or more of the above-identified deficiencies in the art and disadvantages singly or in combination.

According to a first aspect of the inventive concept, these and other objects are achieved in full, or at least in part, by a method for manufacture a semiconductor device, the method comprising a step of providing a substrate having formed thereon or therein a main junction defining a first breakdown voltage, said main junction extending across a first region of the substrate. The method further comprises forming a junction termination structure extending across a second region of the substrate adjacent the main junction. The junction termination structure comprising a plurality of junction termination paths forming closed loops surrounding the main junction, said closed loops being conformal to said main junction. Each path in the plurality of junction termination paths has a path width and comprises an implanted region having an implanted width, wherein a ratio of the implanted width to the path width decreases with increasing distance from the main junction along the surface of the substrate. The substrate is selected to be one of p-doped or n-doped and said implanted regions is selected to be the other of p-doped or n-doped. The step of forming a junction termination structure further comprises determining an individual width for each implanted width and a single dopant dose, wherein said individual width for each implanted width and said single dopant dose corresponds to an individual effective sheet charge concentration for each path in the plurality of junction termination paths such that, when said semiconductor device is in use, a desired electric field distribution over the second region of the semiconductor device is achieved. The step of forming a junction termination structure further comprises doping the implanted regions, each having the individual width, with dopants according to said single dopant dose.

Alternatively, the method comprises a step of providing a substrate having formed thereon or therein a main junction defining a first breakdown voltage, said main junction extending across a first region of the substrate. The method further comprises forming a junction termination structure extending across a second region of the substrate outside the first region. The junction termination structure comprising a plurality of junction termination paths forming closed loops surrounding the main junction, said closed loops being conformal to said main junction. Each path in the plurality of junction termination paths has a path width and comprises an implanted region having an implanted width, wherein a ratio of the implanted width to path width decreases with increasing distance from the main junction along the surface of the substrate. The substrate is selected to be one of p-doped or n-doped and said implanted regions are selected to be the other of p-doped or n-doped. The step of forming a junction termination structure further comprises determining an individual width for each implanted width and a single first dopant dose, N₀, wherein said individual width for each implanted width and said single dopant dose corresponds to an individual effective sheet charge concentration for each path n in the plurality of junction termination paths such that a distribution of effective sheet surface charge is in the region defined by the following formula, N_{SCn}=(N₄−N₀)·xₙ+N₀ for 0≤xₙ≤1, where n=1 to N, N being the number of paths in said plurality junction termination paths, xₙ=xₘₙ/W_{JT} where W_{JT} is the total width of a junction termination path region of the junction termination structure in which the plurality of junction termination paths is provided and xₘₙ is the distance from the start of the junction termination path region to the middle of the n:th path, N₀ is selected in the interval 0.5·N_{sc0}≤N₀≤1.8·N_{sc0}, preferably in the interval 0.8·N_{sc0}≤N₀≤1.3·N_{sc0}, where N_{sc0} is determined from the equation qN_{sc0}=εₛε₀E_{c}, where, εₛ is the dielectric constant of the substrate, ε₀ is the dielectric constant in vacuum and E_{c} is the critical field strength, and N₄ is selected in the interval N₀/10≤N₄≤N₀/2, preferably in the interval N₀/7≤N₄≤N₀/3. The step of forming a junction termination structure further comprises doping the implanted regions, each having the individual width, with dopants according to said first single dopant dose.

By dopant dose, N₀, it may be meant the concentration of electrically active atoms after doping. The dopant dose N₀ may correspond to the sheet charge density of the activated implanted atoms. At 100% activation of implanted species, it may correspond to the implantation dose. Further, the parameter N_{sc0} may refer to a sheet concentration of active dopant atoms.

A first region and a second preferred region may thus be defined using the above formula for a distribution of effective sheet surface charge in the junction termination structure, the said first wide region and a second preferred narrow region. For each selected value of N₀, the formula defines a distribution of effective sheet surface charge in the form of a linear behavior for the range of xₙ. Since N₄<N₀, a distribution of effective sheet surface charge according to the formula above linearly decreases for each selected value of N₀ for increasing xₙ values in the interval 0≤xₙ≤1. Said distribution of effective sheet surface charge resulting at least in part from the doping in the implanted regions may however assume other behaviors than strictly linearly decreasing within said defined region unless otherwise specified and depends at least partly on the doping in the implanted regions.

The individual width for each implanted width and said single dopant dose corresponds to an individual effective sheet charge concentration for each path n in the plurality of junction termination paths such that the distribution of effective sheet surface charge is in this first region or preferably in the second region.

The junction termination path region of the junction termination structure in which the plurality of junction termination paths is provided may start from the edge of the main junction or from an outer edge of an intermediate path if provided between the main junction and the plurality of junction termination paths. The junction termination path region may extend from the edge of the main junction or from said outer edge of an intermediate path if provided between the main junction and the plurality of junction termination paths to an opposite end of the junction termination structure. This extension may be described as a width of the junction termination path region.

Moreover, by having a substrate having formed thereon or therein a main junction it should be understood as the main junction either being formed as a doped section on top of the substrate surface (by for example epitaxial growth) or by doping part of said substrate such that a main junction is formed by a at least a p-n junction between said doped section and the substrate or between the doped part of the substrate and the rest of the substrate adjacent the doped part of the substrate.

The present invention is based on the understanding that there exists a unique sheet charge distribution at the surface yielding a desired electric field distribution. By a desired electric field distribution, it should be understood as an electric field distribution or profile, where the electric field is substantially evenly distributed over the second region of the device, which may be referred to as a substantially uniform electric field distribution. The desired electric field profile may be expressed as an electric field profile having a minimal difference in electrical field between two adjacent junction termination paths when measured over the second region of the device. It should be understood that the electric field distribution becomes more evenly distributed with increasing distance from the surface. Even though this inventive concept provides an improved electric field distribution at the surface of the substrate over the junction termination structure, it has been shown that the electric field distribution is substantially even or uniform from a distance greater than 2 μm or greater than 3 μm from the surface of the junction termination structure. In other words, the desired electric field distribution is substantially uniform over the second region of the junction termination structure, from a distance greater than 2 μm or greater than 3 μm (and at increasing distances) from the junction termination structure. It should be understood that at closer distances to the surface, such as distances up to 1.5 μm from the surface of the second region, the electric field distribution becomes less uniform. The difference in electrical field between two adjacent junction termination paths is typically within 6%, more preferably within 4% most preferably within 2% measured at 1-1.5 μm over the second region of the device for a majority of the junction termination paths arranged in the central part of the junction termination structure. It should be understood that the majority of the plurality junction termination paths arranged in the central part of the junction termination structure typically comprise the 60%-95% of the paths of the plurality of paths and exclude at least the outermost path in the plurality of junction termination paths. In at least one embodiment the innermost path may also be excluded from the majority of the plurality junction termination paths arranged in the central part of the junction termination structure, when for example an intermediate path (which will be further discussed later in the text) is omitted. Another way of defining this is that the deviation of electric field magnitude from the average value of the electric field at a certain distance from the substrate surface (of majority of the junction termination paths) in the central part of the junction termination structure can be relatively small. The deviation of electric field magnitude from the average value of the electric field at a certain distance from the substrate surface (of majority of the junction termination paths) in the central part of the junction termination is typically equal to or less than 30% at a distance of 0.5 μm above the substrate surface, equal to or less than 10% at a distance of 1.0 μm above the substrate surface, equal to or less than 5% at a distance of 1.5 μm above the substrate surface and even smaller at larger distances. Edge effects of the junction termination structure may give rise to increasing difference in electric field of junction termination paths arranged furthest away from the main junction. Further, according to some embodiments herein, edge effects of the junction termination structure may also give rise to increasing difference in electric field of junction termination paths arranged closest to the main junction. Accordingly, the difference in electrical field between the junction termination path arranged closest to the main junction and the junction termination path arranged next closest to the main junction may have a difference in electrical field higher than above specified. In other words, the desired electric field distribution provides a smooth electric field distribution over the second region of the device wherein a maximum of the electric field will be located close to the center of the junction termination structure. In yet other words, by the desired electric field distribution it should be understood as an electrical field distribution over the second region of the device where a maximum in the electric field is close to the mean value of the electrical field distribution over the second region of the device. Hence, a maximum in the electric field may typically be within 2 times, preferably within 1.7 times, more preferably within 1.5 times, most preferably within 1.3 times the mean value of the electric field distribution. The invention is further based on an implementation of the sheet charge distribution by using a single dopant dose. This may typically involve having an implantation using a single masking step under fundamental constraints of limited diffusivity of the dopants in wide bandgap materials like SiC and GaN which prevents the possibility to realize a continuous and smooth distribution of decreasing sheet charge concentration along the device surface. The present invention is furthermore based on the understanding that by determining an individual width for each implanted width and a single dopant dose, an effective sheet charge concentration is achieved for each path in the plurality of junction termination paths, where the effective sheet charge concentration is defined by the ratio of implanted width to path width. This facilitate spreading the electric potential in the lateral direction outward from the edge of the main junction thus reducing the magnitude of the electric field which provides minimum average electric field over the whole second region (termination area). This allows for the desired electric field distribution over the second region of the semiconductor device to be achieved when the semiconductor device is in use. The main junction defines a first breakdown voltage, i.e. the main junction is generally designed to withstand a certain voltage, called the breakdown voltage. The breakdown voltage defines a voltage level at which a current flowing though the main junction suddenly increases when applying a reverse bias to the main junction. Hence, with the provided junction termination structure a breakdown voltage for the semiconductor device is provided that is close to, or the same as, the breakdown voltage defined by the main junction. It should be understood that peaks in the electric field over the second region could adversely affect the breakdown voltage for the semiconductor device and hence the desired electric field distribution is typically a substantially uniform electric field over the junction termination structure. In other words, a breakdown voltage for the semiconductor device is provided that is close to or the same at the breakdown voltage defined by the main junction. Further, the inventive concept provides a minimum lateral expansion of the junction termination for a given breakdown voltage (design voltage), and optimal device chip area utilization, which in turn provides reduced die cost, increases current carrying capability for a given die area, and decreases junction capacitance of the device.

It should be further understood that each path in the plurality of paths are arranged adjacent to each other, such that the paths are arranged at different distances from the main junction along the surface of the substrate. In other words, the paths are arranged next to each forming a continuous junction termination structure from the main junction along the surface of the second region.

Further, it should be understood that the paths may comprise a non-implanted region having an non-implanted width and wherein a ratio of the implanted width to the non-implanted width decreases with increasing distance from the main junction along the surface of the substrate.

By the closed loops being conformal to said main junction it is meant that each closed loop formed by the plurality of junction termination paths are following the contour of the main junction at increasing distance from the main junction. In other words, each closed loop formed by the plurality of junction termination paths are each arranged at the same distance from the main junction along the periphery of the main junction.

The single dopant dose may be determined such that a total depletion of each respective implanted region is achieved when the semiconductor device is exposed to the first breakdown voltage, which may reduce periodic peaks in the electric field along the peripheral area of the main junction and thus further facilitate achieving a substantially uniform electric field over the junction termination structure.

The substrate may be a low doped semiconductor material, typically being one of SiC, GaN and Ga₂O₃.

An epitaxial layer of semiconductor material of the same type as the substrate may be applied onto the second region, which may provide an improved isolation of the junction termination structure. The epitaxial layer may have a thickness of 2-3 μm, which may provide a substantially uniform electric field distribution at the surface of the semiconductor device (above the second region), formed by the epitaxial layer.

A dielectric layer may be arranged onto the epitaxial layer. When arranging the dielectric layer on top of the epitaxial layer, the dielectric layer is subject to a more uniform electric field distribution compared to when arranging the same dielectric layer directly on the junction termination structure after implantation. In the case the dielectric layer is arranged directly on the junction termination structure the dielectric layer will be exposed to higher electric field in case the dielectric constant of dielectric layer is smaller than that of substrate due to the Gauss law. The embedded termination (i.e. the termination structure with the epitaxial layer and the dielectric layer arranged on top) will have higher immunity to the influence of the ambient conditions, surface impurities and charging phenomena in the dielectric. Furthermore, the lifetime and stability over time for the device may be improved by providing lower and uniform electric field in the epitaxial layer and dielectric layers applied over the junction termination and/or the main junction. Typically, the dielectric layer comprises at least one of SiO2, Si3N4 and Al2O3.

According to at least one embodiment, the semiconductor device is manufactured such that the effective sheet surface charge concentration is generally decreasing or monotonously decreasing over an interval of increasing value of xₙ, said interval being continuous or comprising a plurality of separate subintervals of increasing value of xₙ, wherein said interval of increasing value of xₙ corresponds to at least 80% of the full range of 0≤xₙ≤1, or at least 85%, 90%, 95%, 99% or 100% of the full range of 0≤xₙ≤1.

According to at least one embodiment, when the substrate is a low doped semiconductor material being one of SiC, GaN and Ga₂O₃, the distribution of effective sheet surface charge is in accordance with the formula: N_{SCn}=N₀−N₁·xₙ^{p}−N₃·xₙ⁶, where n=1 to N, where N is the number of paths,

$${x}_{n} = \frac{{x}_{mn}}{{W}_{JT}}$$

where W_{JT} is the total width of a junction termination path region of the junction termination structure in which the plurality of junction termination paths is provided and xₘₙ is the distance from the start of the junction termination path region to the middle of the n:th path, p is a value in the interval 0.75≤p≤0.85 or exactly p=0.8, and where furthermore N₃=N₀−N₁−N₂, where N₀, N₁, N₂ and N₃ are sheet charge concentration values. N₀ may correspond to the sheet charge density of the activated implanted atoms (at 100% activation of implanted species it corresponds to the implantation dose).

In the case of GaN, the sheet concentration values N₀, N₁, N₂ may be assigned the following values:

N₀ in the interval of 0.8·10¹³ cm⁻² to 3.5·10¹³ cm⁻², preferably in the interval of 1.4·10¹³ cm⁻² to 2.1·10¹³ cm⁻²;
N₁ in the interval of 0.52·10¹³ cm⁻² to 2.35·10¹³ cm⁻², preferably in the interval of 0.8·10¹³ cm⁻² to 1.1·10¹³ cm⁻²;
N₂ in the interval of 2.0·10¹² cm⁻² to 8.0·10¹² cm⁻², preferably in the interval of 2.0·10¹² cm⁻² to 4.0·10¹² cm⁻².

In the case of SiC, the sheet concentration values N₀, N₁, N₂ may be assigned the following values:

N₀ in the interval of 0.8·10¹³ cm⁻² to 2.2·10¹³ cm⁻², preferably in the interval of 1.2·10¹³ cm⁻² to 1.7·10¹³ cm⁻²;

N₁ in the interval of 0.55·10¹³ cm⁻² to 1.35·10¹³ cm⁻², preferably in the interval of 0.8·10¹³ cm⁻² to 1.1·10¹³ cm⁻²;

N₂ in the interval of 2.0·10¹² cm⁻² to 6.0·10¹² cm⁻², preferably in the interval of 2.0·10¹² cm⁻² to 4.0·10¹² cm⁻².

In the case of Ga₂O₃, the sheet concentration values N₀, N₁, N₂ may be assigned the following values:

N₀ in the interval of 2.3·10¹³ cm⁻² to 8.1·10¹³ cm⁻², preferably in the interval of 3.8·10¹³ cm⁻² to 5.0·10¹³ cm⁻²;

N₁ in the interval of 1.5·10¹³ cm⁻² to 5.35·10¹³ cm⁻², preferably in the interval of 2.5·10¹³ cm⁻² to 2.8·10¹³ cm⁻²;

N₂ in the interval of 0.6·10¹³ cm⁻² to 2.0·10¹³ cm⁻², preferably in the interval of 0.8·10¹³ cm⁻² to 1.2·10¹³ cm⁻².

According to at least one embodiment, the second region further comprises an intermediate path forming a closed loop surrounding the main junction, said closed loop formed by said intermediate path being conformal to said main junction and having second width, said closed loop formed by said intermediate path is arranged between said main junction and said plurality of junction termination paths, the method further comprising doping said intermediate path with said first single dopant dose.

This embodiment is advantageous in reducing peaks in the electric field over the second region of the semiconductor device due to electric field crowding adjacent to the main junction. Accordingly, this embodiment may further facilitate achieving a substantially uniform electric field over the second region of the device adjacent the main junction.

The intermediate path may comprise a first section arranged adjacent the main junction and the method may further comprise doping the first section of the intermediate path with a second dopant dose being higher than the first single dopant dose such that a sheet charge concentration for the first section being higher than the individual effective sheet charge concentration for each path in the plurality of junction termination paths and lower than sheet charge concentration of the main junction is achieved. This may be advantageous in even further reducing the electric field over the second region of the semiconductor device adjacent the main junction due to reducing the difference in sheet charge concentration between the main junction and the intermediate path.

The individual effective sheet charge concentrations for the plurality of junction termination paths are determined to be monotonous decreasing with increasing distance from the main junction. The individual width for each implanted width and the path width of each path in the plurality of junction termination paths are determined such that the effective sheet charge concentration in each path is achieved according to the determined sheet charge concentration.

This facilitate determining the implanted widths and the path width for each path in order to achieve the desired effective sheet charge concentration in the plurality of paths along the surface of the device.

The individual effective sheet charge concentration for each path in the plurality of junction termination paths may be determined according to a polynomial with a predetermined set of control parameters, which may provide facilitated determination of the sheet charge concentration. The polynomial may comprise a constant dependent on the substrate material.

According to a second aspect of the present invention, there is provided a semiconductor device comprising a substrate, a main junction formed on the substrate defining a first breakdown voltage, said main junction extending across a first region of the substrate and a junction termination structure extending across a second region of the substrate adjacent the main junction, the junction termination structure comprising a plurality of paths forming closed loops surrounding the main junction, said closed loops being conformal to said main junction, wherein each path in the plurality of junction termination paths has a path width and comprises an implanted region having an implanted width and a non-implanted region having a non-implanted width, wherein a ratio of the implanted width to path width decreases with increasing distance from the main junction along the surface of the substrate and said substrate is selected to be one of p-doped or n-doped and said implanted regions is selected to be the other of p-doped or n-doped. Each implanted width is an individual width and the implanted regions are doped with a single dopant dose, wherein each implanted width and said single dopant dose corresponds to an individual effective sheet charge concentration for each path in the plurality of junction termination paths such that, when said semiconductor device is in use, a substantially uniform electric field over the second region of the semiconductor device is achieved.

Alternatively, the semiconductor device comprises a substrate; a main junction formed on or in the substrate defining a first breakdown voltage, said main junction extending across a first region of the substrate; a junction termination structure extending across a second region of the substrate outside the main junction. The junction termination structure comprises a plurality of junction termination paths forming closed loops surrounding the main junction, said closed loops being conformal to said main junction. Each path in the plurality of junction termination paths has a path width and comprises an implanted region having an implanted width, wherein a ratio of the implanted width to path width decreases with increasing distance from the main junction along the surface of the substrate and said substrate is selected to be one of p-doped or n-doped and said implanted regions is selected to be the other of p-doped or n-doped. Each implanted width is an individual width and the implanted regions are doped with a single dopant dose, wherein each implanted width and said single dopant dose corresponds to an individual effective sheet charge concentration for each path n in the plurality of junction termination paths such that a distribution of effective sheet surface charge is in the region defined by the following formula, N_{SCn}=(N₄−N₀)·xₙ+N₀ for 0≤xₙ≤1, where n=1 to N, N being the number of paths in the plurality of junction termination paths, xₙ=xₘₙ/W_{JT} where W_{JT} is the total width of a junction termination path region of the junction termination structure in which the plurality of junction termination paths is provided and xₘₙ is the distance from the start of the junction termination path region to the middle of the n:th path, N₀ is selected in the interval 0.5·N_{sc0}≤N₀≤1.8·N_{sc0}, preferably in the interval 0.8·N_{sc0}≤N₀≤1.3·N_{sc0}, Where N_{sc0} is determined from the equation qN_{sc0}=εₛε₀E_{c}, where, εₛ is the dielectric constant of the substrate, ε₀ is the dielectric constant in vacuum and E_{c} is the critical field strength, and N₄ is selected in the interval N₀/10≤N₄≤N₀/2, preferably in the interval N₀/7≤N₄≤N₀/3.

This aspect may exhibit the same or similar features and technical effects as the first aspect, and vice versa.

By dopant dose, N₀, it may be meant the concentration of electrically active atoms after doping. The dopant dose N₀ may correspond to the sheet charge density of the activated implanted atoms. At 100% activation of implanted species, it may correspond to the implantation dose. Further, the parameter N_{sc0} may refer to a sheet concentration of active dopant atoms.

Each implanted region may be doped such that a total depletion of each respective implanted region is achieved when the semiconductor device is exposed to said first breakdown voltage.

The substrate may be a low doped semiconductor material being one of SiC, GaN and Ga₂O₃.

According to one embodiment, the distribution of effective sheet surface charge is in accordance with the formula:

N_{SCn}=N₀−N₁·xₙ^{p}−N₃·xₙ⁶, where n=1 to N,

where N is the number of paths,

$${x}_{n} = \frac{{x}_{mn}}{{W}_{JT}}$$

where W_{JT} is the total width of a junction termination path region of the junction termination structure in which the plurality of junction termination paths is provided and xₘₙ is the distance from the start of the junction termination path region to the middle of the n:th path, p is a value in the interval 0.75≤p≤0.85, and where furthermore N₃=N₀−N₁−N₂, where N₀, N₁, N₂ and N₃ are sheet charge concentration values.

N₀ may correspond to the sheet charge density of the activated implanted atoms (at 100% activation of implanted species it corresponds to the implantation dose).

In the case of GaN, the sheet concentration values N₀, N₁, N₂ may be assigned the following values:

N₀ in the interval of 0.8·10¹³ cm⁻² to 3.5·10¹³ cm⁻², preferably in the interval of 1.4·10¹³ cm⁻² to 2.1·10¹³ cm⁻²;

N₁ in the interval of 0.52·10¹³ cm⁻² to 2.35·10¹³ cm⁻², preferably in the interval of 0.8·10¹³ cm⁻² to 1.1·10¹³ cm⁻²;

N₂ in the interval of 2.0·10¹² cm⁻² to 8.0·10¹² cm⁻², preferably in the interval of 2.0·10¹² cm⁻² to 4.0·10¹² cm⁻².

In the case of SiC, the sheet concentration values N₀, N₁, N₂ may be assigned the following values:

N₀ in the interval of 0.8·10¹³ cm⁻² to 2.2·10¹³ cm⁻², preferably in the interval of 1.2·10¹³ cm⁻² to 1.7·10¹³ cm⁻²;

N₁ in the interval of 0.55·10¹³ cm⁻² to 1.35·10¹³ cm⁻², preferably in the interval of 0.8·10¹³ cm⁻² to 1.1·10¹³ cm⁻²;

N₂ in the interval of 2.0·10¹² cm⁻² to 6.0·10¹² cm⁻², preferably in the interval of 2.0·10¹² cm⁻² to 4.0·10¹² cm⁻².

In the case of Ga₂O₃, the sheet concentration values N₀, N₁, N₂ may be assigned the following values:

N₀ in the interval of 2.3·10¹³ cm⁻² to 8.1·10¹³ cm⁻², preferably in the interval of 3.8·10¹³ cm⁻² to 5.0·10¹³ cm⁻²;

N₁ in the interval of 1.5·10¹³ cm⁻² to 5.35·10¹³ cm⁻², preferably in the interval of 2.5·10¹³ cm⁻² to 2.8·10¹³ cm⁻²;

N₂ in the interval of 0.6·10¹³ cm⁻² to 2.0·10¹³ cm⁻², preferably in the interval of 0.8·10¹³ cm⁻² to 1.2·10¹³ cm⁻².

An epitaxial layer of semiconductor material of the same type as the substrate may be arranged onto the second region, which may provide an improved isolation of the junction termination structure. The epitaxial layer may have a thickness of 2-3 μm, which may provide a substantially uniform electric field distribution at the surface of the semiconductor device, formed by the epitaxial layer.

A dielectric layer may be arranged onto the epitaxial layer or optionally directly on the junction termination structure. When arranging the dielectric layer on top of the epitaxial layer, the dielectric layer is subject to a much more uniform electric field distribution compared to when arranging the same dielectric layer directly on the junction termination structure after implantation. Optionally, said dielectric layer may be applied on top of the semiconductor device to cover both the epitaxial layer and the main junction. The embedded termination (i.e. the termination structure with the epitaxial layer and the dielectric layer arranged on top) will have higher immunity to the influence of the ambient conditions, surface impurities and charging phenomena in the dielectric. Furthermore, the lifetime and stability over time for the device may be improved by providing lower and uniform electric field in the epitaxial layer and dielectric layers applied over the junction termination and/or the main junction. The dielectric layer may comprise at least one of SiO2, Si3N4 and Al2O3.

According to at least one embodiment, the second region further comprises an intermediate path forming a closed loop surrounding the main junction, said closed loop of said intermediate path being conformal to said main junction and having second width, said closed loop of said intermediate path is arranged between said main junction and said plurality of junction termination paths, wherein said intermediate path is doped with said first single dopant dose.

This embodiment is advantageous in reducing peaks in the electric field over the second region of the semiconductor device due to electric field crowding adjacent to the main junction. Accordingly, this embodiment may further facilitate achieving a substantially uniform electric field over the second region of the device adjacent the main junction.

The intermediate path may comprise a first section arranged adjacent the main junction, the first section of the intermediate path is doped with a second dopant dose being higher than the first single dopant dose such that a sheet charge concentration for the first section being higher than the individual effective sheet charge concentration for each path in the plurality of junction termination paths and lower than sheet charge concentration of the main junction is achieved.

This may be advantageous in even further reducing peaks in the electric field over the second region of the semiconductor device due to mitigating electric field crowding adjacent to the main junction due to a large difference in effective sheet charge concentration between that of the main junction and that of the intermediate path by reducing the difference in doping concentration between the main junction and the region right next to it. The second dopant dose may be selected such that the first section implanted by the second dopant dose is not depleted when the semiconductor device is exposed to said first breakdown voltage.

Moreover, it should be understood that any of the features disclosed with the semiconductor device can be used in different method steps. Thus, all features disclosed with one embodiment that is compatible with another embodiment herein is conceivable.

### BRIEF DESCRIPTION OF THE DRAWINGS

These and other aspects of the present invention will now be described in more detail, with reference to the appended drawings showing currently preferred embodiments of the invention.

FIG. 1a is a schematic perspective view of a semiconductor device according to an embodiment of the present invention.

FIG. 1b is a schematic side view of the semiconductor device according to an embodiment of the present invention.

FIG. 2a is a schematic side view of a semiconductor device according to an embodiment of the present invention.

FIG. 2b is a schematic side view of the semiconductor device seen in FIG. 2a and the electric field distribution for the semiconductor device seen in FIG. 2a.

FIG. 2c is a schematic illustration of the electric field over the second region of the device seen in FIG. 2b at different heights from the surface of the second region.

FIG. 3a is a schematic side view of a semiconductor device according to an embodiment of the present invention.

FIG. 3b is a schematic side view of the semiconductor device seen in FIG. 3a including the electric field distribution for the semiconductor device seen in FIG. 3a.

FIG. 3c is a schematic illustration of the electric field over the second region of the device seen in FIG. 3b at different heights from the surface of the second region.

FIG. 4a is a schematic side view of a semiconductor device including the electric field distribution according to an embodiment of the present invention.

FIG. 4b is a schematic illustration of the electric field over the second region of the device seen in FIG. 4a at different heights from the surface.

FIG. 5a-b is a graph of the max and min effective sheet charge concentration over the plurality of junction termination paths for two embodiments of the present invention.

FIG. 6 is a graph of the max and min effective sheet charge concentration over the plurality of junction termination paths according to an embodiment of the present invention.

FIG. 7 is a schematic flow chart illustrating a method according to an embodiment of the present invention;

FIG. 8 is a diagram showing a normalized sheet charge concentration range for a normalized distance at surface for a general case;

FIGS. 9a-9c are diagrams showing sheet charge concentration ranges for a normalized distance at surface for respective specific cases,

FIGS. 10a-10c are diagrams showing sheet charge concentration ranges and polynomials for a normalized distance at surface for respective specific case.

### DETAILED DESCRIPTION OF THE INVENTION

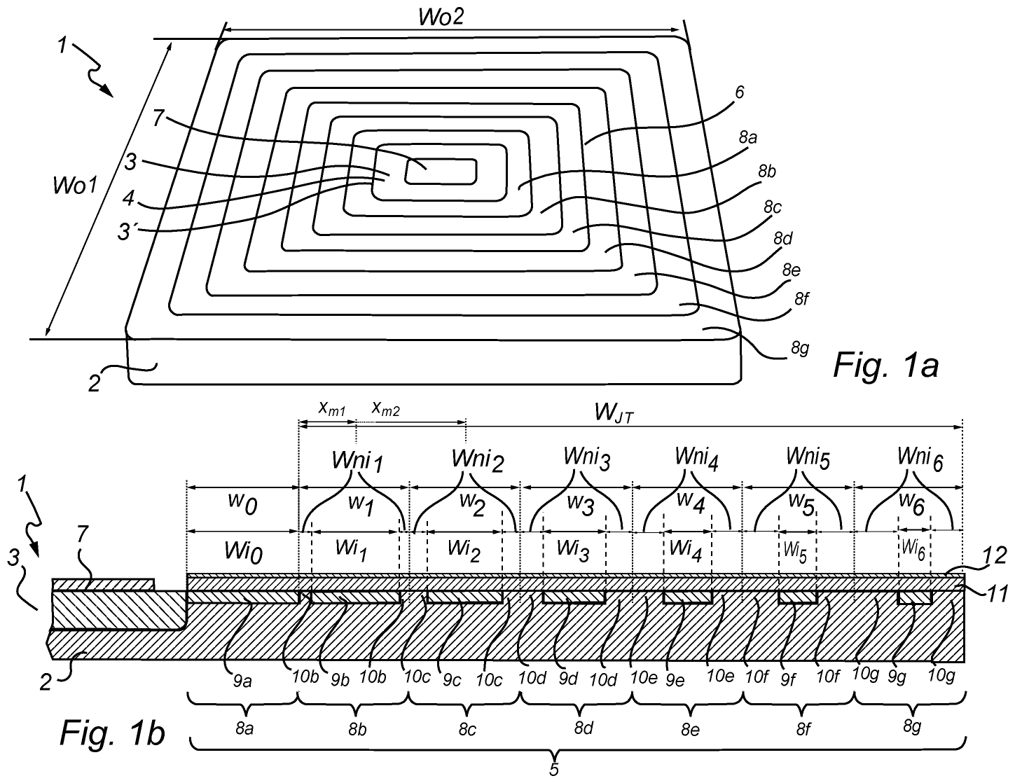

With reference to FIG. 1a-1b a semiconductor device 1 is seen comprising a substrate 2 having formed therein a main junction 3. FIG. 1a, schematically illustrates a perspective view of the semiconductor device 1 and FIG. 1b schematically illustrates a cross-sectional view of the semiconductor device 1 seen in FIG. 1a. The substrate 2 in this sense may also be referred to as the drift region. The substrate 2 is selected to be one of p-doped or n-doped and the main junction 3 forms a p-n junction with the substrate 2. Hence, the main junction 3 is formed by doping part of the substrate 2 with dopants, being of opposite dopant type to the dopant type in the substrate 2. Accordingly, when the substrate 2 is p-doped, the main junction 3 is formed by doping the substrate 2 with n-dopants and when the substrate 2 is n-doped the main junction 3 is formed by doping the substrate 2 with p-dopants. The substrate 2 may in turn be arranged onto a carrier (not shown) or a base substrate (not shown) typically having a higher doping concentration than the substrate 2. Further, the main junction 3 may be at least one of a diode, a transistor (e.g. MOSFET, BJT or JFET), a thyristor or an IGBT. Accordingly, it should be understood that the main junction 3 may comprise additional sections of p- or n-doped material in order to form the main junction 3. As seen in the figure, the main junction 3 is arranged in a first region 4 of the substrate. In the provided example, the main junction 3 is a diode. It should be understood that a plurality of main junctions 3 may be arranged in the first region 4, wherein each junction in the plurality of main junction 3 are arranged in close proximity to each other. A junction termination structure 5 is arranged on a second region 6 of the substrate, the second region 6 being arranged outside the first region 4. The first and second regions 4,6 being part of the substrate surface. The junction termination structure 5 extends across said second region 6 and surrounds the main junction. Hence, the second region 6 surrounds the first region 4.

A contact section 7 is electrically connected to the main junction 3, the contact section 7 may for example connected to the anode or cathode of the main junction 3 when the main junction is a diode. Similarly, when the main junction is for example a transistor, the main junction may comprise more than one contact section 7. When the substrate is n-doped, the more than one contact section 7 may connect to the p-body of a MOSFET or IGBT, p-base of a BJT or thyristor and/or the p-gate of a JFET. When the substrate is p-doped the more than one contact section 7 may connect to the n-body of a MOSFET or IGBT, n-base of a BJT or thyristor and/or the n-gate of a JFET.

The junction termination structure 5 comprising a plurality of junction termination paths 8b-8g forming closed loops surrounding the main junction 3, the closed loops are conformal to said main junction 3. The closed loops follow the contour of the main junction 3 at different distances from the main junction 3. Each path 8b-8g of the plurality of junction termination paths 8b-8g has a width w1, w2, w3, w4, w5, w6 extending orthogonal to the extension of each path 8b-8g. For example, a first path 8b in the plurality of paths 8b-8g is located at distance x, where the distance x is the distance from the edge 3′ of the main junction 3 to the center of the first path 8b in the plurality of junction termination paths 8b-8g and having a width w1, a second path 8c is located at distance x+w1 from the main junction 3 (measured from the edge 3′ of the main junction 3 to the center of the second path 8c) and having a width w2, a third path 8d is located at distance x+w1+w2 from the main junction 3 (measured from the edge 3′ of the main junction 3 to the center of the third path 8d) having a width w3 etc. The first path 8b may be adjacent to the main junction, i.e. x may be ½*W1. It should be understood that the widths w1,w2,w3,w4,w5, w6 of each path 8b-8g is measured parallel to the substrate 2, and orthogonal to the extension of each path 8b-8g in the plurality of junction termination paths 8b-8g. The widths w1, w2,w3,w4,w5,w6 of each path 8b-8g may be different. For example, the widths may decrease with increasing distance from the main junction 3 along the surface of the substrate 2 or the widths may change with increasing distance from the main junction 3 along the surface of the substrate. Alternatively, the widths w1,w2,w3,w4, w5, w6 of each path 8b-8g may be the same. In the provided example, six junction termination paths 8b-8g are arranged on the substrate 2 surrounding the main junction 3. Fewer or more than six junction termination paths 8b-8f may be arranged in the second region 6. Further, in the provided example an intermediate path 8a is arranged in the second region and being part of the junction termination structure 5. The intermediate path 8a forms a closed loop surrounding the main junction 3. The closed loop formed by the intermediate path 8a is conformal to the main junction 3 and having second width w0. The second width w0 may be different to the widths w1-w6 of the paths 8b-8g in the plurality of paths 8b-8g of the junction termination structure 5, or the same as at least one of the widths w1-w6 of the paths 8b-8g. The closed loop formed by the intermediate path 8a is arranged between the main junction 3 and an innermost path, i.e. the first path 8b, of the plurality of junction termination paths 8b-8g. The closed loop formed by the intermediate path 8a is arranged adjacent the main junction 3 in the provided example. However, it should be understood that the intermediate path 8a may be arranged separated from the main junction 3 and/or the innermost path in the plurality of paths at a distance. Alternatively or additionally, the intermediate path 8a may form an extension of the main junction and/or the innermost path in the plurality of paths. Further, the intermediate path 8a in the provide example is adjacent the innermost path of the plurality of junction termination paths 8b-8g. The intermediate path 8a may be doped with the first single dopant dose along its full width. Accordingly, the intermediate path 8a comprises an implanted region 9a with a width equal to the second width w0. The paths 8b-8g of the plurality of junction termination paths 8b-8g are formed adjacent to each other, i.e. the first path 8b is arranged adjacent the second path 8c, the second path 8c is arranged adjacent to the third path 8d, the third path 8d is arranged adjacent to the fourth path 8e and so on. Further, each path 8b-8g of the junction termination paths comprises an implanted region 9b,9c,9d,9e,9f,9g having an implanted width, Wi1, Wi2, Wi3, Wi4, Wi5, Wi6. As the implanted width for each path does not cover the whole respective path width, each path comprises a non-implanted region 10b, 10c, 10d, 10e, 10f, 10g having a non-implanted width Wni1, Wni2, Wni3, Wni4, Wni5, Wni6 wherein a ratio of the implanted width Wi1, Wi2, Wi3, Wi4, Wi5, Wi6 to non-implanted width Wni1, Wni2, Wni3, Wni4, Wni5, Wni6 decreases with increasing distance from the main junction 3 along the surface of the substrate. In the provided example, the implanted region 9b-9g of each path 8b-8g in the plurality of junction termination paths 8b-8g is arranged centered in each path 8b-8g and thus two non-implanted regions 10b-10g are arranged one on each side of the implanted region 9b-9g in each path 8b-8g. Thus the non-implanted width Wni1, Wni2, Wni3, Wni4, Wni5, Wni6 for each path 8b-8g is the sum of the widths of each non-implanted region 10b-10g within each path 8b-8g.

The substrate 2 is selected to be one of p-doped or n-doped and the implanted regions 9b-9g is selected to be the other of p-doped or n-doped. Further, the implanted region 9a of the intermediate path 8a is selected to be of opposite doping to the substrate 2, i.e. the substrate 2 is selected to be one of p-doped or n-doped and the implanted region 9a of the intermediate path 8a is selected to be the other of p-doped and n-doped. In at least one embodiment of the present invention the first path 8b in the plurality of junction termination paths 8b-8g is arranged adjacent the main junction 3. In other words, the intermediate path 8a is optional. By implanting the intermediate path 8a along its full width, electric field crowding adjacent the main junction 3 may be mitigated resulting in a decreased electric field over the surface of the junction termination structure 5 closest to the main junction 3.

The junction termination structure 5 have a total junction termination width being the sum of the widths w1-w6 for each path 8b-8g in the plurality of junction termination paths 8b-8g. When the intermediate path 8a is present, the total junction termination width is the sum of the widths w1-w6 for each path 8b-8g in the plurality of junction termination paths 8b-8g and the width w0 of the intermediate path 8a.

The semiconductor device 1 may be of any shape, such as rectangular, squared or circular. The main junction 3 is preferably arranged centered with respect to the semiconductor device 1. The main junction 3 may comprise of plurality of p-n junctions as p-body region(s) in MOSFET and IGBT, p-base region(s) in BJT and p-gate region(s) in JFET. The footprint of the semiconductor device may be expressed as a function of a first semiconductor width Wd1 and a second semiconductor width Wd2, wherein the first and second semiconductor widths Wd1, Wd2 are orthogonal to each other as illustrated in the provided example. Alternatively, the footprint of the semiconductor device 1 may be expressed as a function of a diameter of the semiconductor device 1. Further, the main junction 3 may have any shape, such as rectangular, squared or circular. Following this, the closed loops formed by the plurality of junction termination paths 8b-8g, and optionally the intermediate path 8a, have a corresponding shape as the main junction 3. In other words, the closed loops are conformal to the main junction 3.

Each implanted width Wi1-Wi6 of the implanted regions in the plurality of paths 8b-8g is an individual width and the implanted regions 9b-9g are doped with a single dopant dose, wherein each implanted width Wi1-Wi6 and said single dopant dose corresponds to an individual effective sheet charge concentration for each path 8b-8g in the plurality of junction termination paths 8b-8g such that, when said semiconductor device 1 is in use, a desired electric field over the second region 6 of the semiconductor device 1 device is achieved. This may be a substantially even electric field over the second region 6 of the semiconductor device 1. This may be realized by the decreasing ratio of the implanted width Wi1-Wi6 to path width W1-W6, and/or decreasing ratio of the implanted width Wi1-Wi6 to non-implanted width Wni1-Wni6, with increasing distance from the main junction 3 along the surface of the substrate 2 and that each implanted region 9b-9g is doped such that a total depletion of each respective implanted region 9b-9g is achieved when the semiconductor device 1 is exposed to said first breakdown voltage. This reduces the peaks in electric field over the second region of the semiconductor device that otherwise would be very distinctive if each implanted region 9b-9g would not be doped such that a total depletion of each respective implanted region 9b-9g is achieved when the semiconductor device 1 is exposed to said first breakdown voltage. It should be understood that by doping the implanted region 9a of the intermediate path 8a with the single dopant dose provides a total depletion of the implanted region 9a of the intermediate path 8a when the semiconductor device 1 is exposed to said first breakdown voltage.

The substrate 2 may be a doped semiconductor material. This doping of the semiconductor material may be within 10¹⁴-10¹⁷ cm⁻³. This may typically be referred to a low doped semiconductor material. The semiconductor material may be one of SiC, GaN and Ga₂O₃. For example, when the substrate 2 is n-doped SiC the implanted regions 9b-9g of the plurality of junction termination paths 8b-8g and optionally the implanted region 9a of the intermediate path 8a when it is present, comprise least one of Al, B, Ga dopants. When the substrate 2 is p-doped SiC the implanted regions 9b-9g of the plurality of junction termination paths 8b-8g and optionally the implanted region 9a of the intermediate path 8a when it is present, comprise at least one of N, Ti, Cr dopants. When the substrate 2 is n-doped GaN the implanted regions 9b-9g of the plurality of junction termination paths 8b-8g and optionally the implanted region 9a of the intermediate path 8a when it is present, comprise at least one of Mg, Zn dopants. When the substrate 2 is p-doped GaN the implanted regions 9b-9g of the plurality of junction termination paths 8b-8g and optionally the implanted region 9a of the intermediate path 8a when it is present, comprise Si dopants. When the substrate 2 is n-doped Ga₂O₃ the implanted regions 9b-9g of the plurality of junction termination paths 8b-8g and optionally the implanted region 9a of the intermediate path 8a when it is present, comprise at least one of Mg, Be, Zn dopants. When the substrate 2 is p-doped Ga₂O₃ the implanted regions 9b-9g of the plurality of junction termination paths 8b-8g and optionally the implanted region 9a of the intermediate path 8a when it is present, comprise at least one of Si, Sn, Ge.

It should be understood that before or after forming the implanted regions 9b-9g of the plurality of paths 8b-8g, and optionally the implanted region 9a of the intermediate path 8a (when it is present), the second region 6 may be doped with an additional doping of opposite doping to the implanted regions 9b-9g of the plurality of paths 8b-8g, and optionally the implanted region 9a of the intermediate path 8a (when it is present). Hence, the additional doping may increase the sheet charge concentration of the substrate 5 (preferably in the non-implanted regions) prior to or after forming the junction termination structure 5. The additional doping may be selected to achieve a doping depth being deeper or more shallow than the doping depth of the implanted regions 9b-9g of the plurality of paths 8b-8g and optionally the implanted region 9a of the intermediate path 8a (when it is present). A typical doping depth of the implanted regions 9b-9g of the plurality of paths 8b-8g, and optionally the implanted region 9a of the intermediate path 8a (when it is present), is in the range of 0.5 to 2.0 μm.

It should further be understood that each implanted region 9b-9g of the plurality of junction termination paths 8b-8g and optionally the implanted region 9a of the intermediate path 8a when it is present, and each non-implanted region 10b-10g are formed as closed loops within each path being conformal to said main junction 3, such that the implanted regions 9b-9g of the plurality of junction termination paths 8b-8g and optionally the implanted region 9a of the intermediate path 8a when it is present, and the non-implanted regions 10b-10g surrounds the main junction 3.

The single dopant dose is typically selected to achieve a sheet charge concentration of the implanted regions in the range 10¹²-10¹⁴ cm⁻². The substrate (drift region) typically have a doping concentration of 10¹⁴-10¹⁷ cm⁻³ The main junction may typically be doped such that the main junction has a sheet charge density between 10¹⁴-10¹⁶ cm⁻²

As illustrated a layer 11 of semiconductor material of the same type as the substrate 2 is arranged onto the second region 6 preferably having the same doping density as that of substrate 2. The layer 11 may have a thickness of between 1-5 μm, preferably between 2-4 μm most preferably between 2-3 μm. The layer 11 may be epitaxially grown onto the substrate 2 over the second region 6, and this the layer 11 may be referred to as an epitaxial layer. The first layer 11 may provide an improved isolation of the junction termination structure 5. This may be referred to as a buried termination. Further, by the first layer 11 having a thickness of more than 2 μm, preferably more than 3 μm may provide a desired electric field distribution when measured at the surface of the semiconductor device 1 (over the second region), i.e. at the surface of the first layer 11.

Further, a dielectric layer 12 may be arranged onto semiconductor device, either directly onto the junction termination structure or onto the first layer 11 as illustrated. The dielectric layer may comprise at least one of SiO2, Si3N4 and Al2O3.

By applying the dielectric layer 12 onto the first layer 11, an improved stability over time and improved lifetime of the semiconductor device 1 may be achieved by providing lower and a desired electric field profile (e.g. a substantially uniform electric field) in the dielectric layer 12 and/or in the first layer applied over the junction termination structure 5 and surface of the semiconductor device 1.

Generally, the dielectric layer 12 reduces the influence of ambient conditions to the junction termination structure 5 and/or the first layer 11 when present.

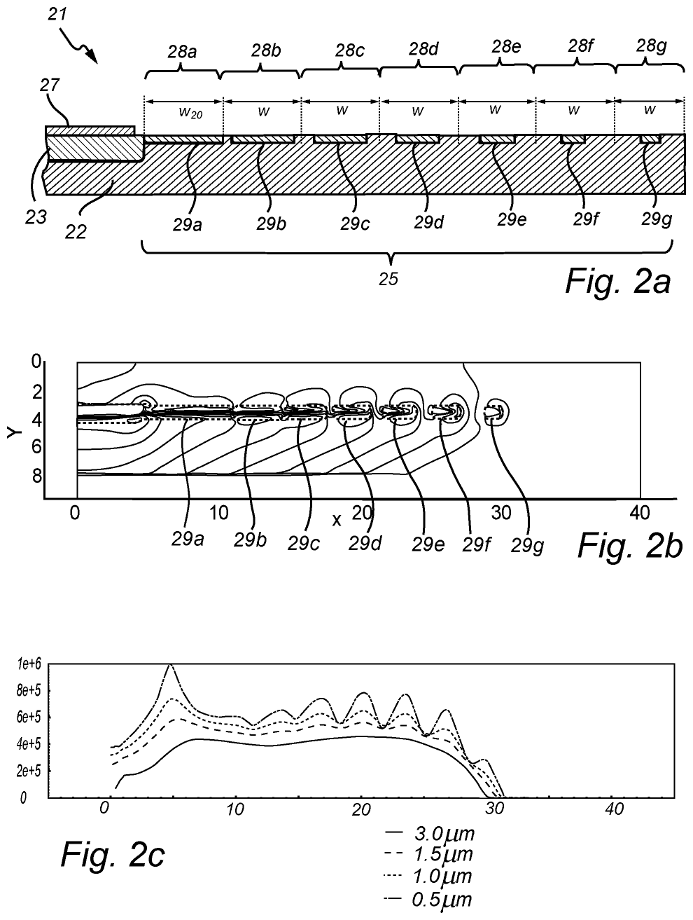

Turning to FIGS. 2a-2c, schematically illustrating a sideview of the semiconductor device 21, the electric field distribution in the semiconductor device 21 and over the surface of the semiconductor device 21, and corresponding electric field profiles measured at different distances over the second region of the semiconductor device 21 according to an embodiment.

The semiconductor device 1 is formed identical to the semiconductor device discussed to FIG. 1, except that each path in the plurality of paths 28b-28g comprises an equal width w, which may facilitate determination of implanted widths to achieve the desired effective sheet charge concentration. However, even though each path in the plurality of paths 28b-28g comprises an equal width w in the provided example, it should be understood that this is not necessary for the inventive concept. In FIG. 2a-2c the second region comprises the intermediate path 28a forming a closed loop surrounding the main junction 23, said closed loop of said intermediate path 28a being conformal to said main junction 23 and having second width w20, which may be different from the widths, w, of the paths 28b-28g in the plurality of paths of the junction termination structure 25. The closed loop of said intermediate path 28a is arranged between said main junction 23 and an innermost path of the plurality of junction termination paths, e.g. the first path 28b according to the illustration. The closed loop of said intermediate path 28a is also doped with said first single dopant dose preferably simultaneously with the doping of the paths 28b-28g in the plurality of paths 28b-28g in the junction termination structure. Accordingly, the junction termination structure comprising the plurality of paths 28b-28g and the intermediate path 28a may be doped in one single doping step, where a single mask may be used.

It should be understood that all implanted regions 29b-29g of the plurality of paths 28a-28g and the implanted region 29a of the intermediate path 28a have the same sheet charge concentration, but with the non-implanted regions 30b-30g in each path 28b-28g in the plurality of paths 28b-28g, the effective sheet charge concentration of the junction termination structure 25 decreases with increasing distance from the main junction 23 along the substrate surface 22. This provides an electric field distribution over the surface of the junction termination structure 25 having a substantially even electric field over the surface, but with some waviness in the electric field measured at the surface of the device. This may be desirable since with increasing distance from the surface of the device (over the junction termination structure) the waviness becomes less apparent such that a substantially even electric field distribution is achieved over the second region at about 2-3 μm from the junction termination structure. The substantially even dielectric field distribution (or substantially uniform electric field distribution) as seen in FIG. 2c is a desired electric field distribution since the distribution has an electric field maximum being close to the mean value of the electric field distribution.

The different electric field distribution or profiles seen in FIG. 2c are electric field profiles at different heights from the surface of the second region, at 0.5 μm, 1.0 μm, 1.5 μm and 3.0 μm respectively. The mean value of the electric field profile decreases with increasing distance from the surface of the junction termination structure 5. Further, the deviation of electric field magnitude from the average (mean) value of the electric field decreases with increasing distance from the substrate. Hence, the deviation of electric field magnitude from the average value of the electric field at a certain distance from the substrate surface in the central part of the junction termination structure can be small. Typically, the deviation of electric field magnitude from the average value of electric field is equal to, or less than, 30% at a distance of 0.5 μm above the substrate surface in the central part of the junction termination structure. Further, the deviation of electric field magnitude from the average value of electric field is typically equal to, or less than, 10% at a distance of 1.0 μm above the substrate surface in the central part of the junction termination structure. Yet further, the deviation of electric field magnitude from the average value of electric field is typically equal to, or less than, 5% at a distance of 1.5 μm above the substrate surface in the central part of the junction termination structure. Further, the deviation of electric field magnitude from the average value of electric field in the central part of the junction termination structure is even smaller at larger distances above the substrate surface in the central part of the junction termination structure. Hence, the deviation of electric field value magnitude from the average value of electric field is typically equal to, or less than, 1% at a distance of 3.0 μm in the central part of the junction termination structure

In FIG. 2b, the electric field is illustrated by field lines. The electric field in the substrate 22 is significantly higher below the main junction 23 compared to the electric field in the substrate 22 below the junction termination structure 25. The electric field is gradually decreasing in the substrate 22 with increasing distance from the main junction 23. At each implanted region 29a-29g of each path 28b-28g in the plurality of junction termination paths 28b-28g and the intermediate path 28a, the electric field is locally increased as seen by the field lines being arranged more dense adjacent each implanted region 29a-29g. However, without the junction termination structure 25 an electric field crowding adjacent the main junction 23 would be expected, accordingly, with the provided junction termination structure 5 an improved electric field distribution is also achieved in the substrate 22, where the electric field is spread over a larger volume of the substrate 22 towards an outer edge of the semiconductor device 21.

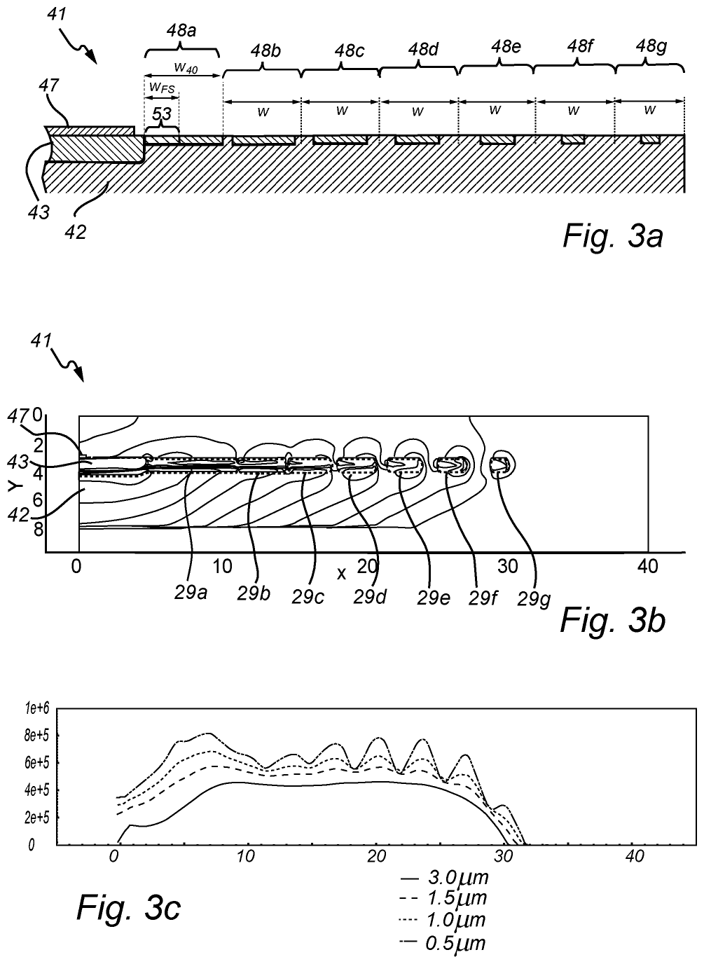

The desired electric field distribution (typically being substantially uniform at 2-3 μm and more over the junction termination structure) achieved over the surface of the junction termination structure may be defined as having close to constant electric field over the majority of the surface with declining electric field towards the edge of the semiconductor device 21. Further, the electric field may increase adjacent the main junction 23. In other words, the desired electric field distribution may have a mean value close to the maximum electric field values achieved over the junction termination structure 25. The maximum electric field value may deviate from the mean value of the electric field distribution over the plurality junction termination paths 28b-28g such that the maximum electric field value of a majority of paths of the plurality of junction termination paths in the central part of the junction termination structure (typically excluding the intermediate path when present) deviate equal to or less than 30% at a distance of 0.5 μm above the substrate surface, equal to or less than 10% at a distance of 1.0 μm above the substrate surface, equal to or less than 5% at a distance of 1.5 μm above the substrate surface and equal or less than 1% at a distance of 3.0 μm above the substrate surface. The central part of the junction termination structure 25 (excluding the intermediate path when present) refer to the area of the substrate covered by paths in the plurality of paths 28b-28g arranged closest to the center part of the junction termination structure 25. Hence, the majority of the plurality junction termination paths 28b-28g arranged in the central part of the junction termination structure typically comprise the 60%-95% of the paths of the plurality of paths 28b-28g and exclude at least the outermost path 28g in the plurality of junction termination paths 28b-28g. In the provided example, when relatively few paths are used (the plurality of junction termination paths comprise six paths 28b-28g), the majority of the junction termination paths 28b-28g arranged in the central part of the junction termination structure 25 typically comprise all paths except the outermost path 28g in the plurality of junction termination paths 28b-28g (i.e. the five paths 28b-28f arranged inside the outermost path). When more paths are used, the majority of the junction termination paths 28b-28g arranged in the central part of the junction termination structure 25 may comprise all paths except the outermost path 28g and at least one more path arranged inside the outermost path 28g. In the provided example, the majority of the junction termination paths 28b-28g, where the desired electric field profile varies according to above, excludes the paths of the junction termination structure arranged at the edges of the junction termination structure where edge effects of the junction termination structure 25 affect the achieved electric field by significantly reducing the electric field distribution over the outermost path. In other words, Edge effect affecting the electric field farthest away from the main junction 23, i.e. electric field values above the outermost paths (paths arranged farthest away from the main junction), is due to natural decrease in the electric field at the edge of the semiconductor device 21. In the provided example, seven paths (including the intermediate path) are provided where the electric field between the outer two paths is rapidly decreasing, affecting the mean value of the electric field distribution. In other words, the electric field over the outer two paths have a greater difference in electric field between two adjacent paths compared to the difference between electric field between two adjacent paths arranged closer to the main junction. Edge effects affecting the electric field close to the main junction 23 is due to electric field crowding next to the main junction 23 giving rise to local increase in the electric field adjacent the main junction 23 which is less apparent with increasing distance from the surface of the semiconductor device 21 (especially from a distance of 3 μm and more from the surface of the junction termination structure 25). The electric field adjacent the main junction 23 is primarily affected by the intermediate path, when it is present. Accordingly, the intermediate path may be further adapted in order to further improve the electric field distribution adjacent the main junction 23 which will be further discussed with reference to FIGS. 3a-c.

Now turning to FIGS. 3a-c showing semiconductor device 41 identical to the semiconductor device discussed in FIGS. 2a-c except that the intermediate path 48a comprises a first section 53 arranged adjacent the main junction 43. The first section 53 of the intermediate path 48a is doped with a second dopant dose such that a sheet charge concentration for the first section 53 being significantly higher than the individual effective sheet charge concentration for each path 48b-48g in the plurality of junction termination paths 48b-48g is achieved. Further, the sheet charge concentration of the first section 53 is less than a sheet charge concentration of the main junction and higher than that of the intermediate path 48a. Hence, it should be understood that the first sheet charge concentration in the first section 53 of the intermediate path 48a is significantly higher than the remaining part of the intermediate path (not being doped with the second dopant dose) and thus also the intermediate path discussed to FIGS. 2a-2c. The width w40 of the intermediate path 48a and the width, w_{FS}, of the first section 53 may be larger or smaller than the path width, w, of the paths 48a-48g in the junction termination. The intermediate path 48a may have a width of up to 100% of the total width of the plurality of paths 48b-48g. In other words, the sum of the widths of the plurality of paths 48b-48g may have the same width as the intermediate path 48a, w₄₀. The width, w_{FS}, of the first section 53 may be selected to be up to 50% of the width of the intermediate path 48a, preferably the first section 53 is less than 50% and more than 10% of the width of the intermediate path 48a, more preferably less than 50% and more than 20% of the width of the intermediate path 48a, most preferably less than 50% and more than 30% of the width of the intermediate path 48a. The width, W_{FS}, of the first section may be adapted based on the electric field achieved adjacent the main junction 43. If it is determined that a certain width of the first section 53 will provide an electric field profile above the intermediate path 48a being undesired (too low or too high), the width may be set to a smaller width (when electric field is too low) or be set to a larger width (when electric field is too high). In other words, the width of the first section may be adapted in order to further facilitate providing the desired electric field profile. Further, the level of dose in the second dopant dose may be adapted based on the electric field achieved adjacent the main junction 43. If it is determined that the second dopant dose will provide an electric field profile above the intermediate path 48a being undesired (too low or too high), the second dopant dose may be set to a lower dopant dose (when electric field is too low) or be set to a higher dopant dose (when electric field is too high). Hence, the second dopant dose may be adapted in order to further facilitate providing the desired electric field profile. The second dopant dose may be selected to achieve a sheet charge concentration in the first section 53 to be in the range of 10¹³-10¹⁵ cm⁻².

Comparing FIG. 2c to FIG. 3c, the effect is seen of introducing the first section 53 according to FIGS. 3a-3c having a significantly higher sheet charge concentration compared to the intermediate path described in FIGS. 2a-c. The electric field adjacent the main junction 43 is further decreased, providing an improved electric field profile adjacent the main junction 43. Hence, doping the first section 53 according to above is advantageous in further achieving a desired electric field profile, especially close to the surface of the substrate above the intermediate path.

Further, reducing the peaks in electric field close to the surface of the intermediate path will reduce the electric field in the epitaxial layer and/or the dielectric layer when respectively present.

The benefits of doping the first section 53 according to above is further seen in FIG. 3b, where the electric field in the substrate has a less dense concentration adjacent the main junction 43 illustrated by the electric field lines, i.e. the electric field in the substrate 42 will be further distributed in the substrate 42. Further a higher electric field is achieved under the main junction compared to the electric field achieved in the substrate under the junction termination structure, wherein the electric field under the main junction is substantially uniform. The provided electric field under the main junction provides high robustness of the semiconductor device due to high sustainable avalanche energy.

Further, the electric field is advantageously kept lower and uniform under the junction termination region. At the same time the electric field under the main junction is also uniform avoiding the field crowding at the edge of the main junction but higher compared to the field in the junction termination structure. This will guarantee high sustainable avalanche energy and high robustness of the device due to the large area subjected to avalanche multiplication.

The electric field profiles in FIG. 3c are corresponding to the electric field profiles in FIG. 2c, except that the electric field profiles in FIG. 3c are based on the semiconductor seen in FIGS. 3a-3b.

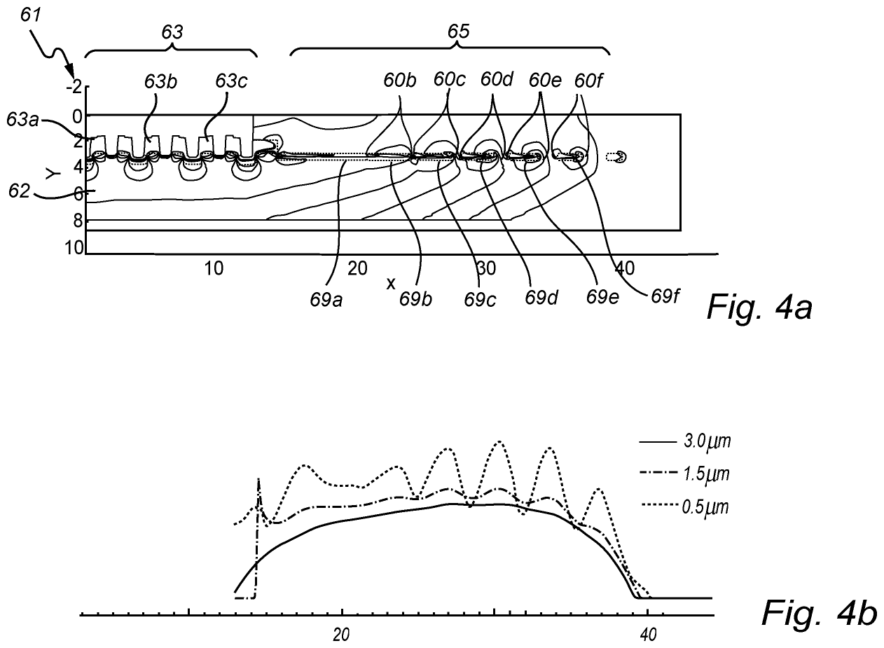

In FIGS. 4a-b a semiconductor device 61 is illustrated identical to the one described in FIGS. 3b-c, except that the main junction 63 comprises a plurality of MOSFET cells 63a,63b,63c arranged adjacent each other. It should however be understood that the widths of the implanted sections 69a-69g, the widths of the non-implanted sections 70b-70g, the widths of the paths 70b-70g in the plurality of junction termination paths and the width of the intermediate path may be adapted to the arrangements of the MOSFET cells 63a, 63b,63c. Further, the MOSFET cells 63a,63b,63c are preferably arranged close to each other such that the spacing between the MOSFET cells is small enough in order to prevent any breakthrough between the MOSFET cells. The MOSFET cells in the provided example are of type trench MOSFET. The electric field is highest right below each MOSFET and by arrangement of the junction termination structure according to the inventive concept the electric field in the substrate is kept at a lower electric field level adjacent the main junction 63 by spreading the electric field over a larger volume of the substrate 62 under the junction termination structure 65 and decreasing with increasing distance from the main junction along the junction termination structure (i.e. parallel to the surface of the substrate). Further a higher electric field is achieved in the substrate under the main junction compared to the electric field achieved in the substrate under the junction termination structure, wherein the maximum electric field under each cell is kept equal providing a large total area subjected to avalanche multiplication under breakdown conditions. The provided electric field under the main junction provides thus high robustness of the semiconductor device due to high sustainable avalanche energy.

In FIG. 4b, the provided electrical field measured at different distances over the surface of the junction termination structure is provided. It is seen that the electric field distribution becomes more even with increasing distance, until a substantially uniform electric field is achieved at about 3 μm over the surface of the junction termination structure. The electric field distribution measured closer to the surface of the junction termination structure is also favorable as the distribution at these distances are also relatively even with minor waviness (minor deviation of maximum electric field compared to the mean value of the electric field over the majority of paths arranged centered in the junction termination structure).

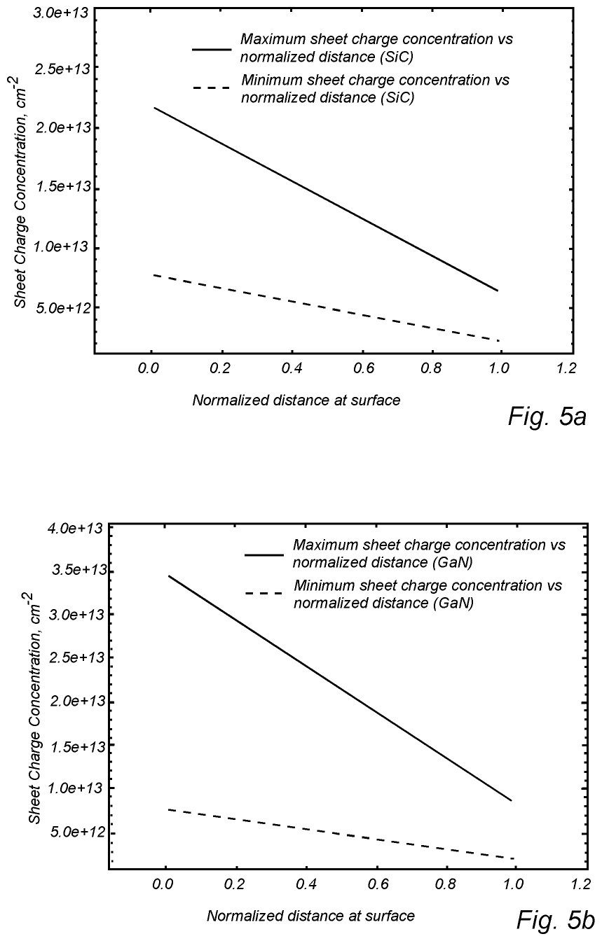

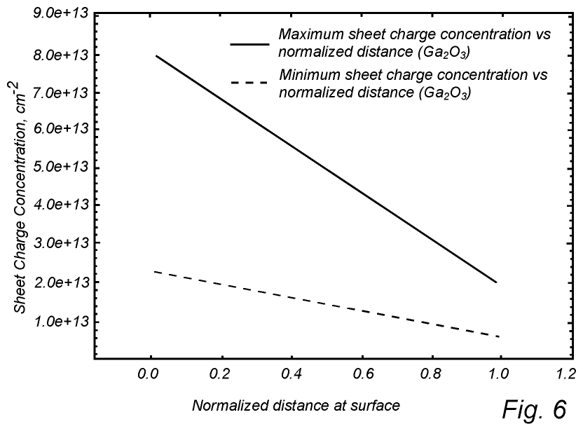

FIGS. 5a-b and FIG. 6 illustrate a maximum and a minimum effective sheet charge concentration as a function of normalized distance from the inner edge of the innermost path (i.e. the first path) of the plurality of junction termination paths for different substrate materials. In other words, the normalized distance is measured from the outer edge of the intermediate paths when it is present. The normalized distance from the inner edge of the innermost path of the plurality of junction termination paths is normalized such that the distance 1.0 determines the outer edge of the semiconductor device and/or the outer edge of the outermost path in the plurality of paths. The effective sheet charge concentration in the respective path should hence be contained within the respective maximum and minimum sheet charge concentration at a given normalized distance from the inner edge of the innermost path for the respective substrate materials. The maximum and minimum sheet charge concentration for the respective substrate materials are defined by the following linear equations:

The maximum sheet charge concentration for SiC, SiC_{maxSCC}, may be expressed as SiC_{maxSCC}=−1.6*10¹³*x+2.2*10¹³.

The minimum sheet charge concentration for SiC, SiC_{minSCC}, may be expressed as SiC_{minSCC}=−6.0*10¹²*x+8.0*10¹².

The maximum sheet charge concentration for GaN, GaN_{maxSCC}, may be expressed as GaN_{maxSCC}=−2.7*10¹³*x+3.5*10¹³.

The minimum sheet charge concentration for GaN, GaN_{minSCC}, may be expressed as GaN_{minSCC}=−6.0*10¹²*x+8.0*10¹².

The maximum sheet charge concentration for Ga₂O₃, Ga₂O_{3maxSCC}, may be expressed as Ga₂O_{3maxSCC}=−6.0*10¹³*x+8.0*10¹³.

The minimum sheet charge concentration for SiC, Ga₂O_{3minSCC}, may be expressed as Ga₂O_{3minSCC}=−1.7*10¹³*x+2.3*10¹³.

Where x in the respective equation above is the distance normalized from the inner edge of the innermost path in the plurality of paths.

Accordingly, when the substrate is SiC the effective sheet charge concentration at the first path (in the plurality of paths) is between 0.8*10¹³ cm⁻² and 2.2*10¹³ cm⁻² according to FIG. 5a. When the substrate is GaN the effective sheet charge concentration at the first path (in the plurality of paths) is between 0.8*10¹³ cm⁻² and 3.5*10¹³ cm⁻² according to FIG. 5b. When the substrate is Ga₂O₃ the effective sheet charge concentration at the first path (in the plurality of paths) is between 2.3*10¹³ and 8.0*10¹³, according to FIG. 6.

The individual effective sheet charge concentration for each path in the plurality of junction termination paths is determined such that the effective sheet charge concentration is monotonous decreasing. Hence, it should be understood that the effective sheet charge may have values that fit within the minimum and maximum values according to the respective figure.

When the effective sheet charge concentration is outside said range (not between the maximum and minimum sheet charge concentration) the electric field distribution is expected to not be uniform, providing a significant peak in the electric field profile. For example, when a too low doping is provided (i.e. a sheet charge concentration below the minimum sheet charge concentration) a breakthrough of electric potential adjacent the main junction is expected providing a peak in the electric field profile in a region close to the main junction. When a too high doping is provided (i.e. a sheet charge concentration above the maximum sheet charge concentration), a peak in the electric field profile in a region close edge of the semiconductor device will be provided.

The sheet charge concentration is generally determined based on the Poissons equation, where the sheet charge concentration, qN_{sc}, is dependent on the dielectric constant of the semiconductor material and its critical field strength according to:

qN_{sc}=εₛε₀E_{c}

Where, εₛ is the dielectric constant of the semiconductor material, ε₀ is the dielectric constant in vacuum and E_{c} is the critical field strength. For SiC, E_{c} is about 2,4 MV*cm⁻¹. For GaN, E_{c} is about 3,4 MV*cm⁻¹. For Ga₂O₃. E_{c} is about 8 MV*cm⁻¹.

The individual effective sheet charge concentration for each path in the plurality of junction termination paths may be determined according to a linear or a polynomial fit with a predetermined set of control parameters. The linear fit or polynomial fit may comprise a constant dependent on the substrate material. When a polynomial is used the polynomial may comprise a variable of 2-8^{th} order in order to achieve a proper fit to the desired sheet charge concentration. For example, when a 6^{th} order polynomial is used the polynomial may comprise a variable of 6th order associated with the distance from the main junction to the center of each respective path in the plurality of junction termination paths divided by the sum of the widths of the plurality of junction termination paths. Preferably, the fit of the effective sheet charge concentration is determined to have an inclination substantially within the inclinations defined by the maximum and minimum values of the effective sheet charge concentration for the respective substrate materials.

The effective sheet charge concentration illustrated by FIGS. 5a-b and FIG. 6 is advantageous in that it could be formulated in normalized form furthermore in that it is generic and valid for any total width of the plurality of paths in the junction termination structure (i.e. the sum of the widths of the plurality of paths) and for any number of paths. It allows further optimization of the junction termination based on four important features
a) algorithm secures uniform and close to constant electric field along the surface of the device,
b) the magnitude of the electric field is controlled by the total width of the plurality of paths (i.e. the magnitude of the electric field is reduced with increased width of the junction termination),
c) the number of paths can be adjusted to meet technological constraints of the lithography (masking) process during implantation since the smaller number of paths results in larger width of nonimplanted paths which can be used to keep the neighbor paths distinctly apart and
d) the number of paths controls furthermore the trade-off between the limitations of the photolithographic process and uniformity of the electric field distribution since larger number of paths results in smoother electric field distribution at given distance from the surface with less pronounced variations.

In order to determine the individual width for each implanted width the path width of each path is set. The path width may be the same for all paths in the plurality of paths or it may be different for at least two paths in the plurality of paths. In one example, the path width may be decreasing with increasing distance from the main junction. Further, the individual width for each implanted width is determined such that the effective sheet charge for each path is achieved according to the determined sheet charge concentration as a function of normalized distance. In other words, the individual width for each implanted width is determined such that the ratio of implanted width to path width for each path achieves the determined effective sheet charge concentration. This may provide the electric field over the junction termination structure of the device to have a desired electric field distribution when the semiconductor device is in use. Accordingly, the implanted width and the single dopant dose correspond to an individual effective sheet charge concentration for each path in the plurality of junction termination paths, where the effective sheet charge concentration is determined to have a monotonously decreasing value as a function of normalized distance from the inner edge of the innermost path of the plurality of junction termination paths. This results in decreasing ratio of the implanted width to path width with increasing distance from the main junction. Further, this results in an electric field distribution being substantially uniform when the semiconductor device is exposed to a voltage being the same or close to the breakdown voltage of the main junction.

It should be further understood that the total width of the paths in the plurality of paths may be adapted to the design voltage for the main junction. With increasing design voltage a larger junction termination structure may be provided, i.e. a larger total width of the plurality of paths. Further, the number of paths may also be adapted according to the design voltage for the main junction and/or the total width of the plurality of paths. With increasing number of paths and/or increasing design voltage, the junction termination structure may be divided into increasing number of paths (keeping the total width of the plurality of paths constant). In other words, the junction termination structure may comprise a number of paths dependent on the design voltage of the main junction.

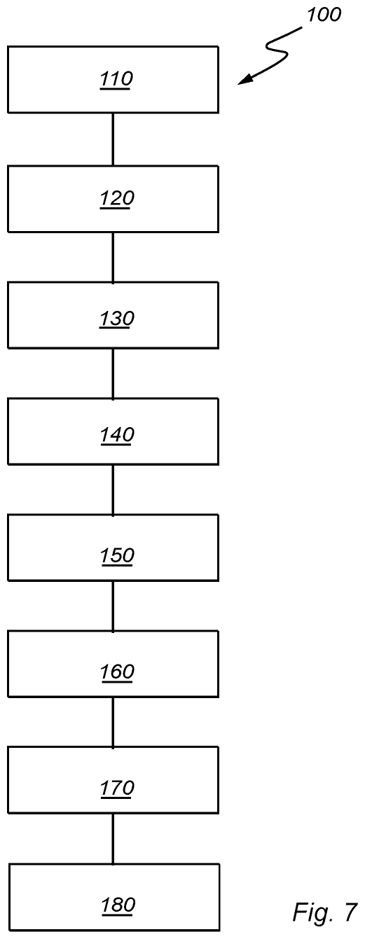

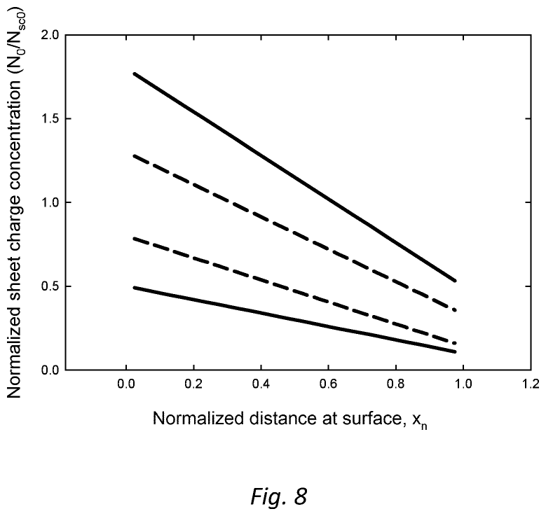

Turning to FIG. 7 illustrating a flowchart of a method 100 for manufacture a semiconductor device. The method comprising providing 110 a substrate having formed thereon or therein a main junction defining a first breakdown voltage, said main junction extending across a first region of the substrate and forming 120 a junction termination structure extending across a second region of the substrate outside the first region. The junction termination structure comprising a plurality of junction termination paths forming closed loops surrounding the main junction, the closed loops being conformal to the main junction. Each path in the plurality of junction termination paths has a width and comprises an implanted region having an implanted width. A ratio of the implanted width to path width decreases with increasing distance from the main junction along the surface of the substrate. The substrate is selected to be one of p-doped or n-doped and said implanted regions is selected to be the other of p-doped or n-doped. the step of forming 120 a junction termination structure comprises determining 130 an individual width for each implanted width and a single first dopant dose. The individual width for each implanted width and the single dopant dose corresponds to an individual effective sheet charge concentration for each zone path in the plurality of junction termination zones paths such that, when said semiconductor device is in use, a substantially uniform electric field over the surface of the second region of the semiconductor device is achieved. The method further comprises doping 140 the implanted regions, each having the individual width, with dopants according to said first single dopant dose.

The substrate may be a low doped semiconductor material, such as one of SiC, GaN and Ga₂O₃.

The method may further comprise applying 150 a first layer of semiconductor material of the same type as the substrate onto the second region. The first layer may have a thickness of 2-3 μm. Preferably, the first layer is applied epitaxially onto the second region and may thus be referred to an epitaxial layer. The method may further comprise applying 160 a dielectric layer onto the junction termination structure. The dielectric layer may be applied directly onto the substrate, at least covering the junction termination structure, or it may be applied onto the first layer when the first layer is present. The dielectric layer may preferably comprise at least one of SiO2, Si3N4 and Al2O3.

The step of forming 120 a junction termination structure may further comprise forming an intermediate path forming a closed loop surrounding the main junction, said closed loop formed by said intermediate path being conformal to said main junction and having second width, said closed loop formed by said intermediate path is arranged between said main junction and an innermost path of said plurality of junction termination paths.

The step of doping 140 the implanted regions may further comprise doping 170 the intermediate path with the first single dopant dose. Hence, it should be understood that the step of doping 140 the implanted regions may, when the intermediate path is present, comprise doping the implanted regions and the intermediate path in one single step of doping. Accordingly, the step of doping 140 may comprise applying a single mask such that the junction termination structure and optionally the intermediate path is doped with the first single dopant dose. Hence, it should be understood that the junction termination structure and the intermediate path (when it is present) may be provided by a single doping step using a single mask.

The intermediate path may comprise a first section arranged adjacent the main junction. Hence it should be understood that the step of forming 120 a junction termination structure may comprise forming the first section of the intermediate path. The method may further comprise doping 180 the first section of said intermediate path with a second dopant dose such that a sheet charge concentration for the first section being higher than the individual effective sheet charge concentration for each path in the plurality of junction termination paths is achieved. The second dopant dose may be significantly higher than the first single dopant dose. The doping of the first section may further be adapted such that the sheet charge concentration achieved in the first section is lower than a sheet charge concentration of the main junction.

As described, the junction termination structure comprises a plurality of junction termination paths forming closed loops surrounding the main junction, said closed loops being conformal to said main junction. Each path in the plurality of junction termination paths has a path width and comprises an implanted region having an implanted width, wherein a ratio of the implanted width to path width decreases with increasing distance from the main junction along the surface of the substrate and said substrate is selected to be one of p-doped or n-doped and said implanted regions is selected to be the other of p-doped or n-doped.

Each implanted width is an individual width, and the implanted regions are doped with a single dopant dose, wherein each implanted width and said single dopant dose corresponds to an individual effective sheet charge concentration for each path n in the plurality of junction termination paths such that a distribution of effective sheet surface charge is in the region defined by the following formula,

$${N}_{SCn} = ( {N}_{4} - {N}_{0} ) \cdot {x}_{n} + {N}_{0} for 0 \leq {x}_{n} \leq 1 ,$$

where n=1 to N, N being the number of paths in the plurality of junction termination paths, xₙ=xₘₙ/W_{JT} where W_{JT} is the total width of a junction termination path region of the junction termination structure in which the plurality of junction termination paths is provided and xₘₙ is the distance from the start of the junction termination path region to the middle of the n:th path (see FIG. 1b), N₀ is selected in the interval 0.5·N_{sc0}≤N₀≤1.8·N_{sc0}, preferably in the interval 0.8·N_{sc0}≤N₀≤1.3. N_{sc0}, where N_{sc0} is determined from the equation qN_{sc0}=εₛε₀E_{c}, where, εₛ is the dielectric constant of the substrate, ε₀ is the dielectric constant in vacuum and E_{c} is the critical field strength, and N₄ is selected in the interval N₀/10≤N₄≤N₀/2, preferably in the interval N₀/7≤N₄≤N₀/3.

FIG. 8 shows regions of normalized sheet charge concentration; a first region is defined as the region between the upper solid line and the lower solid line, and a second region, which may be referred to as a preferred region, is defined as the region between the upper dashed line and the lower dashed line.

The upper solid line is obtained from the above formula by selecting N₀ and N₄ to be the maximal values of the intervals of N₀ and N₄ specified above, respectively.

The lower solid line is obtained from the above formula by selecting N₀ and N₄ to be the minimal values of the intervals of N₀ and N₄ specified above, respectively.

The upper dashed line is obtained from the above formula by selecting N₀ and N₄ to be the maximal values of the preferred intervals of N₀ and N₄ specified above, respectively.

The lower dashed line is obtained from the above formula by selecting N₀ and N₄ to be the minimal values of the preferred intervals of N₀ and N₄ specified above, respectively.

Generally, the semiconductor device is manufactured such that the effective sheet surface charge concentration is generally decreasing or monotonously decreasing over an interval of increasing value of xₙ, said interval being continuous or comprising a plurality of separate subintervals of increasing value of xₙ, wherein said interval of increasing value of xₙ corresponds to at least 80% of the full interval of 0≤xₙ≤1.

For example, the effective sheet surface charge concentration is generally decreasing for increasing xₙ in the interval 0≤xₙ≤1. The effective sheet surface charge concentration may be constant for one or more subintervals in the interval 0≤xₙ≤1. Said one or more subintervals may be selected from the group of following subintervals: 0.00≤xₙ≤0.05, 0.05≤xₙ≤0.10, 0.10≤xₙ≤0.15, 0.15≤x≤0.20, 0.20≤xₙ≤0.25, 0.25≤xₙ≤0.30, 0.30≤xₙ≤0.35, 0.35≤x≤0.40, 0.40≤xₙ≤0.45, 0.45≤xₙ≤0.50, 0.50≤xₙ≤0.55, 0.55≤xₙ≤0.60, 0.60≤xₙ≤0.65, 0.65≤xₙ≤0.70, 0.70≤xₙ≤0.75, 0.75≤xₙ≤0.80, 0.80≤xₙ≤0.85, 0.85≤xₙ≤0.90, 0.90≤xₙ≤0.95, 0.95≤xₙ≤1.00. The effective sheet surface charge concentration may be increasing in one or more subintervals, as long as the total subinterval(s) of xₙ for which the effective sheet surface charge concentration decreases is at least 80% of the whole interval of 0≤xₙ≤1. The effective sheet surface charge concentration may be decreasing at least 85%, 90%, 95% or 99% of the whole interval of 0≤xₙ≤1

For example, the effective sheet surface charge concentration is monotonously decreasing for increasing xₙ in the interval 0≤xₙ≤1.

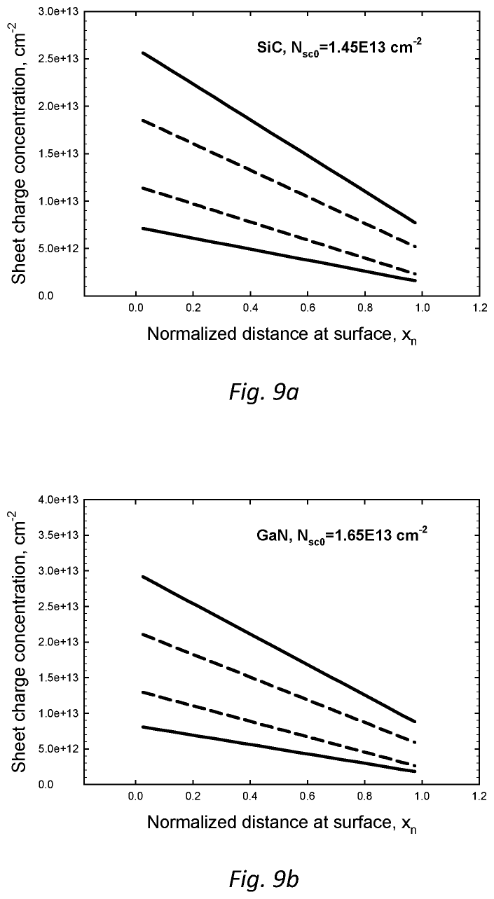

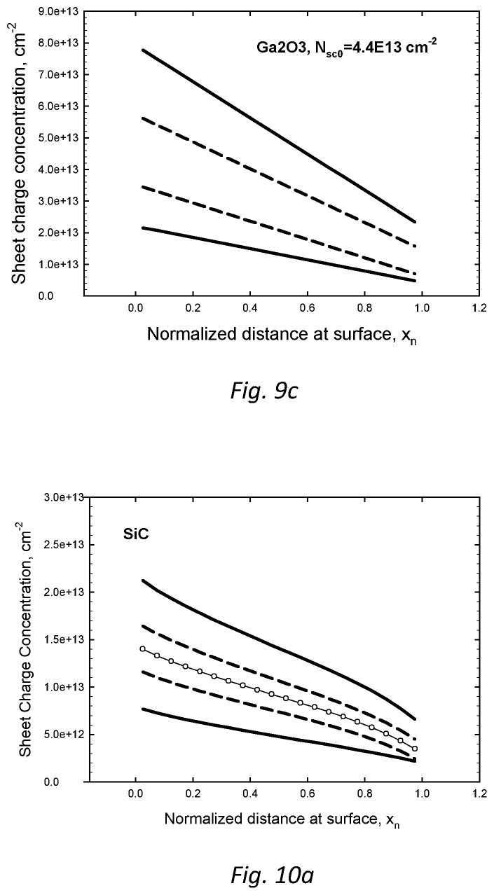

FIGS. 9a-9c show regions of sheet charge concentration for specific cases, respectively. Contrary to FIG. 8, the sheet charge concentration is not normalized. The value of N_{sc0} is determined from the equation qN_{sc0}=εₛε₀E_{c}, where, εₛ is the dielectric constant of the substrate, ε₀ is the dielectric constant in vacuum and E_{c} is the critical field strength for the material used. Similar to FIG. 8, each of the FIGS. 9a-9c show a first region which is defined as the region between an upper solid line and a lower solid line, and a second region, which may be referred to as a preferred region, which is defined as the region between a lower dashed line and an upper dashed line.

FIG. 9a show regions of sheet charge concentration for the specific case when the substrate is a low doped semiconductor material of SiC. For this particular material, the value of N_{sc0}=1.45E13 cm⁻² and the respective regions, maximal region and preferred region, are illustrated accordingly.

FIG. 9b show regions of sheet charge concentration for the specific case when the substrate is a low doped semiconductor material of GaN. For this particular material, the value of N_{sc0}=1.65E13 cm⁻² and the respective regions, maximal region and preferred region, are illustrated accordingly.

FIG. 9c show regions of sheet charge concentration for the specific case when the substrate is a low doped semiconductor material of Ga₂O₃. For this particular material, the value of N_{sc0}=4.4E13 cm⁻² and the respective regions, maximal region and preferred region, are illustrated accordingly.

The semiconductor device is manufactured so that the sheet charge concentration for the respective cases is in the respective first region and preferably in the second region, and preferably generally decreasing or monotonously decreasing over the interval of increasing value of xₙ, said interval being continuous or comprising a plurality of separate subintervals of increasing value of xₙ, wherein said interval of increasing value of xₙ corresponds to at least 80% of the full interval of 0≤xₙ≤1.

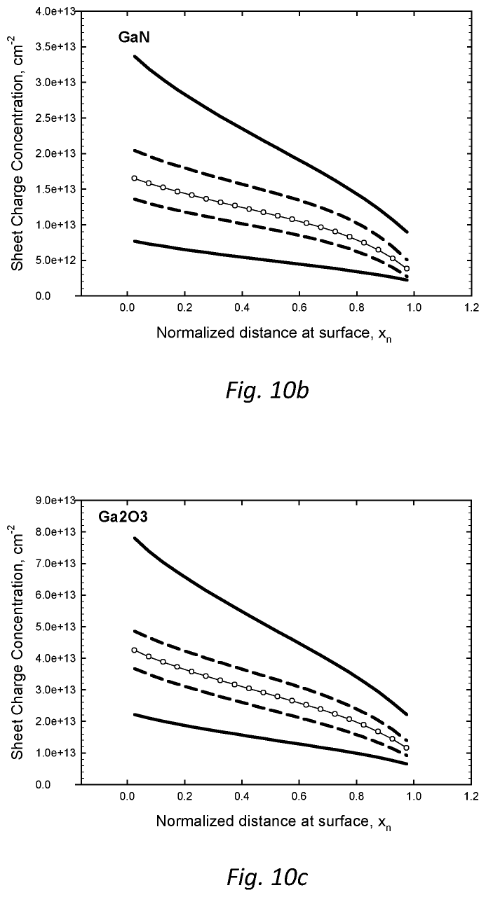

FIGS. 10a-10c show regions of sheet charge concentration for various specific cases wherein a respective polynomial fit of the sheet concentration charge is provided also. When the substrate is a low doped semiconductor material being one of SiC, GaN and Ga₂O₃, the distribution of effective sheet surface charge can be selected to be in accordance with the formula describing the above polynomial fit:

$${N}_{SCn} = {N}_{0} - {N}_{1} \cdot {x}_{n}^{p} - {N}_{3} \cdot {x}_{n}^{6} ,$$

where n=1 to N, where N is the number of paths, with xₙ=xₘₙ/W_{JT} where W_{JT} is the total width of the region of the junction termination structure in which the plurality of junction termination paths is provided and xₘₙ is the distance from the start of this region to the middle of the n:th path, p is a value in the interval 0.75≤p≤0.85 or exactly p=0.8, and where furthermore N₃=N₀−N₁−N₂, where N₀, N₁, N₂ and N₃ are sheet charge concentration values. N₀ may correspond to the sheet charge density of the activated implanted atoms (at 100% activation of implanted species it corresponds to the implantation dose).

In the case of SiC, the sheet concentration values N₀, N₁, N₂ are assigned the following values:

N₀ in the interval of 0.8·10¹³ cm⁻² to 2.2·10¹³ cm⁻², preferably in the interval of 1.2·10¹³ cm⁻² to 1.7·10¹³ cm⁻²;

N₁ in the interval of 0.55·10¹³ cm⁻² to 1.35·10¹³ cm⁻², preferably in the interval of 0.8·10¹³ cm⁻² to 1.1·10¹³ cm⁻²:

N₂ in the interval of 2.0·10¹² cm⁻² to 6.0·10¹² cm⁻², preferably in the interval of 2.0·10¹² cm⁻² to 4.0·10¹² cm⁻².

In the case of GaN, the sheet concentration values N₀, N₁, N₂ are assigned the following values:

N₀ in the interval of 0.8·10¹³ cm⁻² to 3.5·10¹³ cm⁻², preferably in the interval of 1.4·10¹³ cm⁻² to 2.1·10¹³ cm⁻²;

N₁ in the interval of 0.52·10¹³ cm⁻² to 2.35·10¹³ cm⁻², preferably in the interval of 0.8·10¹³ cm⁻² to 1.1·10¹³ cm⁻²;

N₂ in the interval of 2.0·10¹² cm⁻² to 8.0·10¹² cm⁻², preferably in the interval of 2.0·10¹² cm⁻² to 4.0·10¹² cm⁻².

In the case of Ga₂O₃, the sheet concentration values N₀, N₁, N₂ are assigned the following values:

N₀ in the interval of 2.3·10¹³ cm⁻² to 8.1·10¹³ cm⁻², preferably in the interval of 3.8·10¹³ cm⁻² to 5.0·10¹³ cm⁻²;

N₁ in the interval of 1.5·10¹³ cm⁻² to 5.35·10¹³ cm⁻², preferably in the interval of 2.5·10¹³ cm⁻² to 2.8·10¹³ cm⁻²;

N₂ in the interval of 0.6·10¹³ cm⁻² to 2.0·10¹³ cm⁻², preferably in the interval of 0.8·10¹³ cm⁻² to 1.2·10¹³ cm⁻².

The effective sheet charge concentration of the semiconductor device according to the invention or a semiconductor device manufactured according to the invention may be measured and/or determined as follows. In a first step, after successive removal of protective layers of the semiconductor device, optical and scanning electron microscopy (SEM) can be used to uncover masking pattern on the top surface used to create dopant distribution and resulting surface charge distribution. SEM may then be applied to a sample cross-section revealing doping/implantation depth and geometry. In a second step, scanning capacitance microscopy (SCM) can be applied to both top surface and cross-section surface to determine doping distribution. Potential distribution at the top surface can be measured by high resistive probe under applied bias. The derivation of the potential distribution yields electric field distribution. Combining the above steps allows determining the JTE design and the effective sheet charge concentration.

### ITEMIZED LIST OF EMBODIMENTS

Item 1. A method (100) for manufacture a semiconductor device, the method comprising:

providing (110) a substrate having formed thereon or therein a main junction defining a first breakdown voltage, said main junction extending across a first region of the substrate;

forming (120) a junction termination structure extending across a second region of the substrate outside the first region, the junction termination structure comprising a plurality of junction termination paths forming closed loops surrounding the main junction, said closed loops being conformal to said main junction, wherein each path in the plurality of junction termination paths has a path width and comprises an implanted region having an implanted width, wherein a ratio of the implanted width to path width decreases with increasing distance from the main junction along the surface of the substrate, and said substrate is selected to be one of p-doped or n-doped and said implanted regions is selected to be the other of p-doped or n-doped;

characterized in that

the step of forming (120) a junction termination structure comprises

determining (130) an individual width for each implanted width and a single first dopant dose, wherein said individual width for each implanted width and said single dopant dose corresponds to an individual effective sheet charge concentration for each path in the plurality of junction termination paths such that, when said semiconductor device is in use, a desired electric field distribution over the second region of the semiconductor device is achieved, and

doping (140) the implanted regions, each having the individual width, with dopants according to said first single dopant dose.

Item 2. The method according to Item 1, wherein the single dopant dose is determined such that a total depletion of each respective implanted region is achieved when the semiconductor device is exposed to said first breakdown voltage.
Item 3. The method according to Item 1 or 2, wherein the substrate is a low doped semiconductor material being one of SiC, GaN and Ga₂O₃.
Item 4. The method according to any one of the preceding Items, wherein the method comprises

applying (150) an epitaxial layer of semiconductor material of the same type as the substrate onto the second region, optionally said epitaxial layer has a thickness of 2-3 μm.

Item 5. The method according to Item 4, wherein the method further comprises

applying (160) a dielectric layer onto the epitaxial layer, optionally said dielectric layer comprise at least one of SiO2, Si3N4 and Al2O3.

Item 6. The method according to any one of the preceding Items, wherein the second region further comprises an intermediate path forming a closed loop surrounding the main junction, said closed loop formed by said intermediate path being conformal to said main junction and having second width, said closed loop formed by said intermediate path is arranged between said main junction and an innermost path of said plurality of junction termination paths, the step of doping (140) the implanted regions further comprising

doping (170) said intermediate path with said first single dopant dose.

Item 7. The method according to Item 6, wherein said intermediate path comprises a first section arranged adjacent the main junction, the method further comprising

doping (180) said first section of said intermediate path with a second dopant dose being higher than the first single dopant dose such that a sheet charge concentration for the first section being higher than the individual effective sheet charge concentration for each path in the plurality of junction termination paths and lower than a sheet charge concentration of the main junction is achieved.

Item 8. The method according to any one of the preceding Items, wherein said individual effective sheet charge concentration for the plurality of junction termination paths are determined to be monotonous decreasing with increasing distance from the main junction and wherein the individual width for each implanted width and the path width of each path in the plurality of junction termination paths are determined such that the effective sheet charge concentration in each path is achieved according to the determined sheet charge concentration.
Item 9. The method according to Item 8, wherein the effective sheet charge concentration for the plurality of junction termination paths are determined according to a polynomial with a predetermined set of control parameters.
Item 10. A semiconductor device comprising

a substrate;

a main junction formed on or in the substrate defining a first breakdown voltage, said main junction extending across a first region of the substrate;
a junction termination structure extending across a second region of the substrate outside the main junction, the junction termination structure comprising
a plurality of junction termination paths forming closed loops surrounding the main junction, said closed loops being conformal to said main junction, wherein each path in the plurality of junction termination paths has a path width and comprises
   an implanted region having an implanted width,
   wherein a ratio of the implanted width to path width decreases with increasing distance from the main junction along the surface of the substrate and said substrate is selected to be one of p-doped or n-doped and said implanted regions is selected to be the other of p-doped or n-doped;
      characterized in that each implanted width is an individual width and the implanted regions are doped with a single dopant dose, wherein each implanted width and said single dopant dose corresponds to an individual effective sheet charge concentration for each path in the plurality of junction termination paths such that, when said semiconductor device is in use, a desired electric field distribution over the surface of the semiconductor device is achieved.
      Item 11. The semiconductor device according to Item 10, wherein each implanted region is doped such that a total depletion of each respective implanted region is achieved when the semiconductor device is exposed to said first breakdown voltage.
      Item 12. The semiconductor device according to any one of Item 10-11, wherein the substrate is a low doped semiconductor material being one of SiC, GaN and Ga₂O₃.
      Item 13. The semiconductor device according to any one of Item 10-12, wherein an epitaxial layer of semiconductor material of the same type as the substrate is arranged onto the second region, optionally said epitaxial layer has a thickness of 2-3 μm.
      Item 14. The semiconductor device according to any one of Items 10-13, wherein the second region further comprises an intermediate path forming a closed loop surrounding the main junction, said closed loop of said intermediate path being conformal to said main junction and having second width, said closed loop of said intermediate path is arranged between said main junction and an innermost path of the plurality of junction termination paths, wherein said intermediate path is doped with said first single dopant dose.
      Item 15. The semiconductor device according to Item 14, wherein said intermediate path comprises a first section covering at least part of the intermediate path arranged adjacent the main junction, said first section of said intermediate path is doped with a second dopant dose being higher than the first single dopant dose such that a sheet charge concentration for the first section being higher than the individual effective sheet charge concentration for each path in the plurality of junction termination paths and lower than a sheet charge concentration of the main junction is achieved.

1. A method for manufacture a semiconductor device, the method comprising:
providing a substrate having formed thereon or therein a main junction defining a first breakdown voltage, said main junction extending across a first region of the substrate; and
forming a junction termination structure extending across a second region of the substrate outside the first region, the junction termination structure comprising a plurality of junction termination paths forming closed loops surrounding the main junction, said closed loops being conformal to said main junction, wherein each path in the plurality of junction termination paths has a path width and comprises an implanted region having an implanted width, wherein a ratio of the implanted width to path width decreases with increasing distance from the main junction along the surface of the substrate, and said substrate is selected to be one of p-doped or n-doped and said implanted regions is selected to be the other of p-doped or n-doped,
wherein the step of forming the junction termination structure comprises:
determining an individual width for each implanted width and a single first dopant dose, wherein said individual width for each implanted width and said single dopant dose corresponds to an individual effective sheet charge concentration for each path n in the plurality of junction termination paths such that a distribution of effective sheet surface charge is in the region defined by the following formula:
$${N}_{SCn} = ( {N}_{4} - {N}_{0} ) \cdot {x}_{n} + {N}_{o} for 0 \leq {x}_{n} \leq 1 ,$$
where: n=1 to N, N being the number of paths in said plurality junction termination paths,
xₙ=xₘₙW_{jT} where W_{jT} is the total width of a junction termination path region of the junction termination structure in which the plurality of junction termination paths is provided and xₘₙ is the distance from the start of the junction termination path region to the middle of the n:th path,
Nₒ is selected in the interval from 0.5·N_{sc0}≤N₀≤1.8·N_{sc0}, preferably 0.8·N_{sc0}≤N₀≤1.3·N_{sc0}, where N_{sc0} is determined from the equation qN_{sc0}=εₛε₀E_{c}, where, εₛ is the dielectric constant of the substrate, ε₀ is the dielectric constant in vacuum and E_{c} is the critical field strength, and N₄ is selected in the interval Nₒ/10≤N₄≤N₀/2, preferably in the interval Nₒ/7≤N₄≤N₀/3, and
doping the implanted regions, each having the individual width, with dopants according to said first single dopant dose.

2. The method according to claim 1, wherein the semiconductor device is manufactured such that the effective sheet surface charge concentration is generally decreasing or monotonously decreasing over an interval of increasing value of xₙ, said interval being continuous or comprising a plurality of separate subintervals of increasing value of xₙ, and
wherein said interval of increasing value of xₙ corresponds to at least 80% of the full interval of 0≤xₙ≤1.

3. The method according to claim 1, wherein the substrate is a low doped semiconductor material being one of SiC, GaN and Ga₂O₃.

4. The method according to claim 3, wherein the distribution of effective sheet surface charge is in accordance with the formula:
$${N}_{SCn} = {N}_{0} - {N}_{1} \cdot {x}_{n}^{p} - {N}_{3} \cdot {x}_{n}^{6} , where n = 1 to N ,$$
where: N is the number of paths,
$${x}_{n} = \frac{{x}_{mn}}{{W}_{JT}}$$
where W_{jT} is the total width of a junction termination path region of the junction termination structure in which the plurality of junction termination paths is provided and xₘₙ is the distance from the start of the junction termination path region to the middle of the n:th path,
p is a value in the interval 0.75≤p≤0.85, and N₃=N₀−N₁−N₂, where N₀, N₁, N₂ and N₃ are sheet charge concentration values.

5. The method according to claim 1, wherein the method comprises applying an epitaxial layer of semiconductor material of the same type as the substrate onto the second region, and optionally said epitaxial layer has a thickness of 2-3 pm.

6. The method according to claim 5, wherein the method further comprises applying a dielectric layer onto the epitaxial layer, and optionally said dielectric layer comprise at least one of SiO₂, Si₃N₄ and Al₂O₃.

7. The method according to claim 1, wherein the second region further comprises an intermediate path forming a closed loop surrounding the main junction, said closed loop formed by said intermediate path being conformal to said main junction and having second width, said closed loop formed by said intermediate path is arranged between said main junction and an innermost path of said plurality of junction termination paths, and
wherein the step of doping the implanted regions further comprises doping said intermediate path with said first single dopant dose.

8. The method according to claim 7, wherein said intermediate path comprises a first section arranged adjacent the main junction, and
wherein the method further comprises:
doping said first section of said intermediate path with a second dopant dose being higher than the first single dopant dose such that a sheet charge concentration for the first section being higher than the individual effective sheet charge concentration for each path in the plurality of junction termination paths and lower than a sheet charge concentration of the main junction is achieved.

9. The method according to claim 1, wherein said individual effective sheet charge concentration for the plurality of junction termination paths are determined to be monotonous decreasing with increasing distance from the main junction, and
wherein the individual width for each implanted width and the path width of each path in the plurality of junction termination paths are determined such that the effective sheet charge concentration in each path is achieved according to the determined sheet charge concentration.

10. The method according to claim 9, wherein the effective sheet charge concentration for the plurality of junction termination paths are determined according to a polynomial with a predetermined set of control parameters.

11. A semiconductor device, comprising:
a substrate;
a main junction formed on or in the substrate defining a first breakdown voltage, said main junction extending across a first region of the substrate;
a junction termination structure extending across a second region of the substrate outside the main junction,
wherein the junction termination structure comprises a plurality of junction termination paths forming closed loops surrounding the main junction, said closed loops being conformal to said main junction,
wherein each path in the plurality of junction termination paths has a path width and comprises an implanted region having an implanted width,
wherein a ratio of the implanted width to path width decreases with increasing distance from the main junction along the surface of the substrate and said substrate is selected to be one of p-doped or n-doped and said implanted regions is selected to be the other of p-doped or n-doped,
wherein each implanted width is an individual width and the implanted regions are doped with a single dopant dose,
wherein each implanted width and said single dopant dose corresponds to an individual effective sheet charge concentration for each path n in the plurality of junction termination paths such that a distribution of effective sheet surface charge is in the region defined by the following formula:
$${N}_{SCn} = ( {N}_{4} - {N}_{0} ) \cdot {x}_{n} + {N}_{o} for 0 \leq {x}_{n} \leq 1 ,$$
where: n=1 to N, N being the number of paths in said plurality junction termination paths,
xₙ=xₘₙ/W_{jT} where W_{jT} is the total width of a junction termination path region of the junction termination structure in which the plurality of junction termination paths is provided and xₘₙ is the distance from the start of the junction termination path region to the middle of the n:th path,
Nₒ is selected in the interval from 0.5·N_{sc0}≤N₀≤1.8·N_{sc0}, preferably 0.8·N_{sc0}≤N₀≤1.3·N_{sc0}, where N_{sc0} is determined from the equation qN_{sc0}=εₛε₀E_{c}, where, εₛ is the dielectric constant of the substrate, ε₀ is the dielectric constant in vacuum and E_{c} is the critical field strength, and
N₄ is selected in the interval Nₒ/10≤N₄≤N₀/2, preferably in the interval Nₒ/7≤N₄≤N₀/3.

12. The semiconductor device according to claim 11, wherein the effective sheet surface charge concentration is generally decreasing or monotonously decreasing over an interval of increasing value of xₙ, said interval being continuous or comprising a plurality of separate subintervals of increasing value of xₙ, and
wherein said interval of increasing value of xₙ corresponds to at least 80% of the full interval of 0≤xₙ≤1.

13. The semiconductor device according to claim 11, wherein the substrate is a low doped semiconductor material being one of SiC, GaN and Ga₂O₃.

14. The semiconductor device according to claim 13, wherein the distribution of effective sheet surface charge is in accordance with the formula:
$${N}_{SCn} = {N}_{0} - {N}_{1} \cdot {x}_{n}^{p} - {N}_{3} \cdot {x}_{n}^{6} , where n = 1 to N ,$$
where: N is the number of paths,
$${x}_{n} = \frac{{x}_{mn}}{{W}_{JT}}$$
where W_{jT} is the total width of a junction termination path region of the junction termination structure in which the plurality of junction termination paths is provided and xₘₙ is the distance from the start of the junction termination path region to the middle of the n:th path,
p is a value in the interval 0.75≤p≤0.85, and N₃=N₀−N₁−N₂, where N₀, N₁, N₂ and N₃ are sheet charge concentration values.

15. The semiconductor device according to claim 11, wherein an epitaxial layer of semiconductor material of the same type as the substrate is arranged onto the second region, and optionally said epitaxial layer has a thickness of 2-3 pm.

16. The semiconductor device according to claim 11, wherein the second region further comprises an intermediate path forming a closed loop surrounding the main junction, said closed loop of said intermediate path being conformal to said main junction and having second width, said closed loop of said intermediate path is arranged between said main junction and an innermost path of the plurality of junction termination paths, and
wherein said intermediate path is doped with said first single dopant dose.

17. The semiconductor device according to claim 15, wherein said intermediate path comprises a first section covering at least part of the intermediate path arranged adjacent the main junction, said first section of said intermediate path is doped with a second dopant dose being higher than the first single dopant dose such that a sheet charge concentration for the first section being higher than the individual effective sheet charge concentration for each path in the plurality of junction termination paths and lower than a sheet charge concentration of the main junction is achieved.
